(19) United States
(12) Patent Application Publication
(10) Pub. No.: US 2026/0164556 A1
(43) Pub. Date: Jun. 11, 2026

(54) ELECTRIC MODULE AND ELECTRIC DEVICE

(71) Applicant: CANON KABUSHIKI KAISHA, Tokyo (JP)

(72) Inventors: SATORU HIGUCHI, Tokyo (JP); MITSUTOSHI HASEGAWA, Kanagawa (JP)

(21) Appl. No.: 19/414,797

(22) Filed: Dec. 10, 2025

(30) Foreign Application Priority Data
Dec. 11, 2024 (JP) 2024-217045

(51) Int. Cl. H05K 1/14; H05K 5/00; H04N 23/54

(52) U.S. Cl. CPC H05K 1/144; H05K 5/0026; H04N 23/54; H05K 2201/042

(57) ABSTRACT

An electric module includes a first electric board, and a second electric board. The first electric board has a first main surface, a second main surface provided on an opposite side to the first main surface, and a first end surface. The second electric board has a third main surface, a fourth main surface provided on an opposite side to the third main surface, and a second end surface. The first main surface and the third main surface are electrically interconnected by being bonded to each other via a first bonding member. A first angle formed between the first main surface and the first end surface on an inner side of the first electric board and/or a second angle formed between the third main surface and the second end surface on an inner side of the second electric board are each an obtuse angle of 105° or less.

### BACKGROUND

### Field of the Technology

The present disclosure relates to an electric module and an electric device.

### Description of the Related Art

In an electric module incorporated in an electric device, a three-dimensional mounting structure in which a plurality of boards are bonded together is employed. Japanese Patent Application Laid-Open No. 2015-50355 discloses a three-dimensional mounting structure including a board, a first electronic component bonded onto the board via a bonding member such as solder, a second electronic component bonded onto the first electronic component via a bonding member, and a reinforcement resin portion disposed between the second electronic component and the board at the four corners of the second electronic component or the vicinity thereof.

However, depending on the three-dimensional mounting structure, there is a case where stress is concentrated on the bonding member as a result of impact from dropping or change in the temperature, and thus the reliability of the bonding at the bonding member is insufficient.

### SUMMARY

The present disclosure provides a technique advantageous for improving the reliability of bonding.

According to a first aspect of the present disclosure, an electric module includes a first electric board, and a second electric board. The first electric board has a first main surface, a second main surface provided on an opposite side to the first main surface, and a first end surface connected to the first main surface and the second main surface. The second electric board has a third main surface, a fourth main surface provided on an opposite side to the third main surface, and a second end surface connected to the third main surface and the fourth main surface. The first main surface of the first electric board and the third main surface of the second electric board are electrically interconnected by being bonded to each other via a first bonding member. A first angle formed between the first main surface and the first end surface on an inner side of the first electric board and/or a second angle formed between the third main surface and the second end surface on an inner side of the second electric board are each an obtuse angle of 105° or less.

According to a second aspect of the present disclosure, an electric module includes a first electric board, and a second electric board. The first electric board has a first main surface, a second main surface provided on an opposite side to the first main surface, and a first end surface connected to the first main surface and the second main surface. The second electric board has a third main surface, a fourth main surface provided on an opposite side to the third main surface, and a second end surface connected to the third main surface and the fourth main surface. The first main surface of the first electric board and the third main surface of the second electric board are electrically interconnected by being bonded to each other via a first bonding member. The first main surface of the first electric board and the second end surface of the second electric board are opposed to each other in a direction orthogonal to the first main surface. At least an angle formed between the third main surface and the second end surface on an inner side of the second electric board is an obtuse angle of 120° or less.

Features of the present disclosure will become apparent from the following description of embodiments with reference to the attached drawings. The following description of embodiments is described by way of example.

### BRIEF DESCRIPTION OF THE DRAWINGS

FIG. 1 is an explanatory diagram of a digital camera serving as an example of a system according to a first embodiment.

FIG. 2A is a perspective view of a processing module according to the first embodiment.

FIG. 2B is a side view of the processing module according to the first embodiment.

FIG. 3 is a section view of the processing module according to the first embodiment.

FIG. 4A is a plan view of a wiring board according to the first embodiment.

FIG. 4B is a plan view of the wiring board according to the first embodiment.

FIG. 4C is a plan view of the processing module according to the first embodiment.

FIG. 5 is a section view of part of the processing module according to the first embodiment.

FIG. 6 is a plan view of a processing module according to a second embodiment.

FIG. 7A is a section view of the processing module according to the second embodiment.

FIG. 7B is a side view of the processing module according to the second embodiment.

FIG. 8 is a section view of part of the processing module according to the second embodiment.

FIG. 9 is a plan view of a processing module according to a third embodiment.

FIG. 10 is a section view of the processing module according to the third embodiment.

FIG. 11A is an explanatory diagram of a digital camera serving as an example of a system according to a fourth embodiment.

FIG. 11B is a perspective view of an electric module according to the fourth embodiment.

FIG. 12A is a section view of the electric module according to the fourth embodiment.

FIG. 12B is a plan view of a wiring board according to the fourth embodiment.

FIG. 13A is a section view of an electric module according to a fifth embodiment.

FIG. 13B is a section view of an electric module according to a modification example of the fifth embodiment.

FIG. 14A is a section view of an electric module according to a sixth embodiment.

FIG. 14B is a section view of an electric module according to a modification example of the sixth embodiment.

FIG. 15 is an explanatory diagram of a lens unit according to a seventh embodiment.

FIG. 16 is a section view of an electric module according to the seventh embodiment.

### DESCRIPTION OF THE EMBODIMENTS

Embodiments of the present disclosure will be described in detail below with reference to drawings. For example, details of the configurations of the embodiments described below can be appropriately modified for implementation by one skilled in the art within the gist of the present disclosure.

To be noted, in the drawings referred to in the description of the embodiments below, elements denoted by the same reference signs have substantially the same functions unless described otherwise. In the case where a plurality of the same elements are disposed in the drawing, addition of the reference sign and description thereof may be omitted. In addition, since the drawings may be expressed schematically for the sake of convenience of illustration and description, the shapes, sizes, and layouts of the elements illustrated in the drawings do not necessarily strictly match those of the elements illustrated in other drawings or those in reality.

In the description below, the directions are indicated in an XYZ coordinate system that is an orthogonal coordinate system. The X axis, the Y axis, and the Z axis are orthogonal to each other. In addition, the direction of the X axis may be also referred to as an X direction, the direction of the Y axis may be also referred to as a Y direction, and the direction of the Z axis may be also referred to as a Z direction. In addition, for example, a +X direction indicates a direction indicated by an X-axis arrow in the illustrated coordinate system, and a -X direction indicates a direction opposite to the direction indicated by the X-axis arrow in the illustrated coordinate system. In addition, in the case where a direction is simply referred to as an X direction, this indicates a direction parallel to the X axis regardless of whether or not the direction is the same as the direction indicated by the X-axis arrow in the illustration. The same applies to the Y axis and the Z axis other than the X axis. In addition, for example, a plane including the X axis and the Y axis will be expressed as an XY plane. The same applies to an XZ plane and a YZ plane.

### First Embodiment

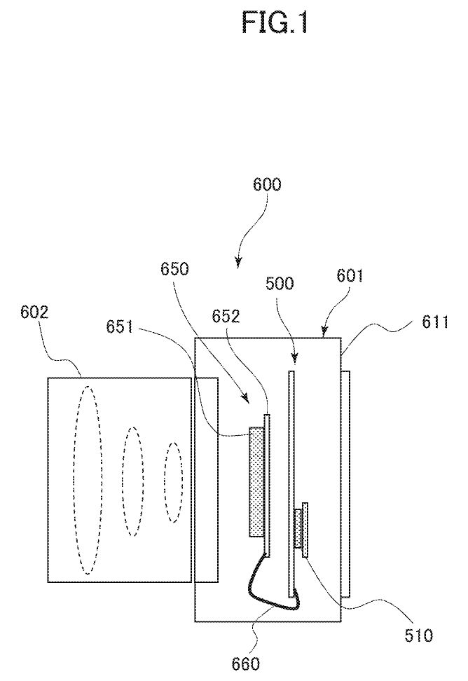

FIG. 1 is an explanatory diagram of a digital camera 600 serving as an example of a system according to a first embodiment. The digital camera 600 is a digital camera of a lens-replacing type in the present example, and includes a camera body 601 serving as an example of an electric device. A lens unit 602 including a lens is attachable to and detachable from the camera body 601. To be noted, the digital camera 600 is not limited to a digital camera of a lens-replacing type, and may be a digital camera of a lens-integrated type in which the camera body 601 and the lens unit 602 are integrated. The camera body 601 includes a casing 611, and a processing module 500 and a sensor module 650 that are disposed inside the casing 611. The processing module 500 and the sensor module 650 are each an example of an electric module. The processing module 500 is a three-dimensional mounting structure. The processing module 500 and the sensor module 650 are electrically interconnected by a wiring component 660.

The wiring component 660 can have flexibility, and may be, for example, a flexible wiring board or a flexible flat cable. A signal indicating image data generated in the sensor module 650 is transmitted to the processing module 500 via the wiring component 660.

The sensor module 650 includes an image sensor 651 that is an image pickup device, and a wiring board 652. The image sensor 651 is mounted on the wiring board 652. The image sensor 651 is, for example, a complementary metal oxide semiconductor (CMOS) image sensor or a charge coupled device (CCD) image sensor. The image sensor 651 has a function to convert light incident through the lens unit 602 into an electric signal.

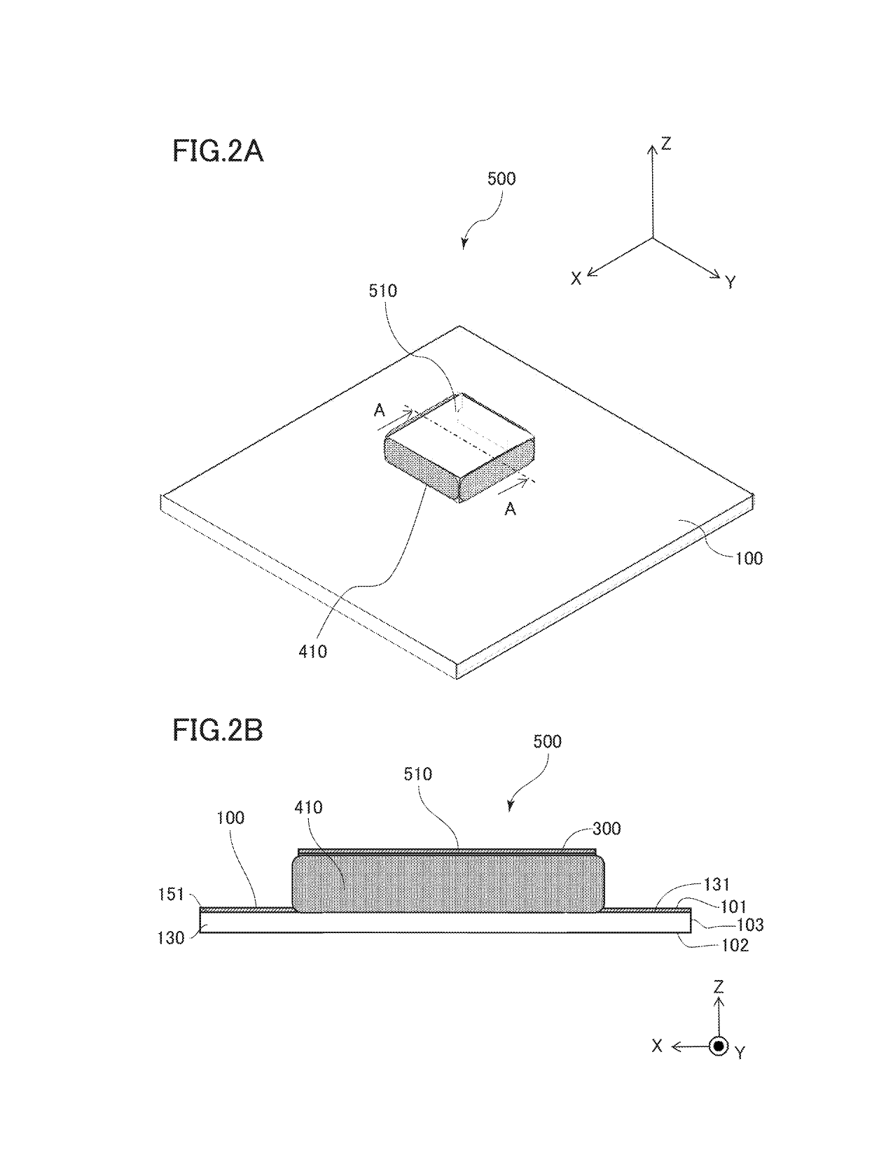

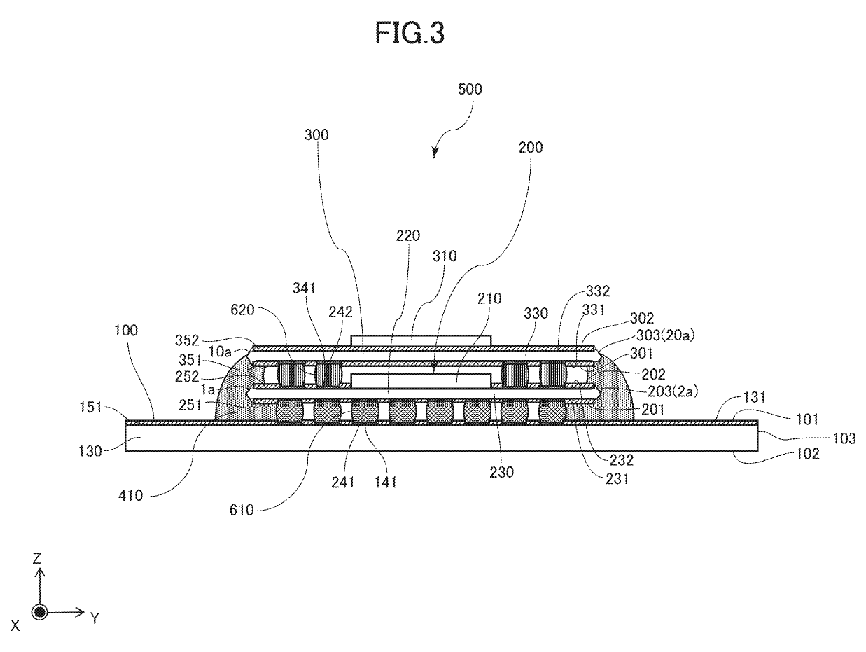

FIG. 2A is a perspective view of the processing module 500 according to the first embodiment. FIG. 2B is a side view of the processing module 500 according to the first embodiment. FIG. 2B illustrates the processing module 500 as viewed in the -Y direction. FIG. 3B is a section view of the processing module 500 according to the first embodiment. FIG. 3 is a section view of the processing module 500 according to the first embodiment. FIG. 3 illustrates a cross-section of the processing module 500 taken along a plane A-A illustrated in FIG. 2. The plane A-A is a virtual plane parallel to the YZ plane.

Here, the Z direction is also a direction in which the processing module 500 is viewed in plan view. In addition, viewing in the Z direction, that is, viewing in plan view also includes viewing through something in the Z direction. In addition, the expression “in the Z direction” can also include “as viewed in the Z direction”.

The processing module 500 includes a wiring board 100, a mounting structure 510 mounted on the wiring board 100, and a resin reinforcement member 410 formed from resin and surrounding the mounting structure 510. The mounting structure 510 is a structure that is mounted three-dimensionally.

The mounting structure 510 includes a semiconductor device 200 bonded onto the wiring board 100 via a plurality of bonding members 610, a wiring board 300 bonded onto the semiconductor device 200 via a plurality of bonding members 620, and a semiconductor element 310 mounted on the wiring board 300. The plurality of bonding members 610 are each an example of a first bonding member. The plurality of bonding members 620 are each an example of a second bonding member. The plurality of bonding members 610 are each formed from a conductive member such as solder. The plurality of bonding members 620 are each formed from a conductive member such as solder.

The semiconductor device 200 is, for example, a digital signal processor, and has a function to obtain an electric signal from the image sensor 651, perform processing to correct the obtained electric signal, and thus generate image data. The resin reinforcement member 410 is formed from resin, and the mounting structure 510 is fixed to the wiring board 100 thereby.

The semiconductor device 200 is a semiconductor package of an area array, and is a semiconductor package of a ball grid array (BGA) in the first embodiment. The semiconductor device 200 includes a wiring board 220, and a semiconductor element 210 mounted on the wiring board 220.

The wiring board 100 is an example of a first electric board, and is a rigid board. The wiring board 220 is an example of a second electric board, and is a rigid board. The wiring board 300 is an example of a third electric board, and is a rigid board.

The wiring board 100 has a main surface 101 serving as an example of a first main surface, a main surface 102 serving as an example of a second main surface, and an end surface 103 serving as an example of a first end surface. The main surface 102 is a main surface on the opposite side to the main surface 101. The main surface 101 and the main surface 102 are each a mounting surface. The end surface 103 is an outer peripheral surface of the wiring board 100 positioned between the main surfaces 101 and 102 and connected to the main surfaces 101 and 102.

The wiring board 100 includes an insulating substrate 130, a plurality of pads 141 disposed on a main surface 131 of the insulating substrate 130, and a solder resist film 151 disposed around the plurality of pads 141 and on the main surface 131 of the insulating substrate 130.

The main surface 101 of the wiring board 100 includes the surface of the solder resist film 151 and the surface of the plurality of pads 141 exposed through the solder resist film 151. That is, the solder resist film 151 and the plurality of pads 141 are disposed on the main surface 101 side (that is, the main surface 131 side). To be noted, the main surface 101 may include part of the main surface 131 of the insulating substrate 130 exposed through the solder resist film 151.

The plurality of pads 141 may be arranged in a lattice pattern, that is, in a matrix pattern, a peripheral pattern, or a staggered pattern. The plurality of pads 141 are each a terminal formed from a metal material that is a conductive material, such as copper or gold.

The material of the insulating substrate 130 is, for example, glass epoxy. The solder resist film 151 is a film formed from a solder resist material. The plurality of pads 141 are each exposed through an opening portion provided in the solder resist film 151. The pad 141 may be a solder mask define (SMD) pad or a non-solder mask defined (NSMD) pad, and is an SMD pad in the first embodiment.

For example, the semiconductor element 210 mainly includes a semiconductor such as silicon. The wiring board 220 is, for example, a printed board or an interposer. The wiring board 220 has a main surface 201 serving as an example of a third main surface, a main surface 202 serving as an example of a fourth main surface, and an end surface 203 serving as an example of a second end surface. The main surface 202 is a main surface on the opposite side to the main surface 201. The main surface 201 and the main surface 202 are each a mounting surface. The main surface 101 of the wiring board 100 and the main surface 201 of the wiring board 220 oppose each other in the Z direction. The end surface 203 is an outer peripheral surface of the wiring board 220 positioned between the main surfaces 201 and 202 and connected to the main surfaces 201 and 202. The semiconductor element 210 is mounted on the main surface 202.

The wiring board 220 includes an insulating substrate 230. The insulating substrate 230 has a main surface 231 and a main surface 232 on the opposite side to the main surface 231. The material of the insulating substrate 230 is, for example, glass epoxy.

In addition, the wiring board 220 includes a plurality of pads 241 disposed on the main surface 231 of the insulating substrate 230 and a plurality of pads 242 disposed on the main surface 232 of the insulating substrate 230. The plurality of pads 241 may be arranged in a lattice pattern, that is, in a matrix pattern, a staggered pattern, or a peripheral pattern. The plurality of pads 241 are arranged to respectively oppose the plurality of pads 141 in the Z direction. The plurality of pads 242 are, for example, arranged in a peripheral pattern along the outer periphery of the semiconductor element 210. The plurality of pads 241 and 242 are each a terminal formed from a metal material that is a conductive material, such as copper or gold.

In addition, the wiring board 220 includes a solder resist film 251 disposed around the plurality of pads 241 and on the main surface 231 of the insulating substrate 230, and a solder resist film 252 disposed around the plurality of pads 242 and on the main surface 232 of the insulating substrate 230.

The main surface 201 of the wiring board 220 includes the surface of the solder resist film 251 and the surface of the plurality of pads 241 exposed through the solder resist film 251. That is, the solder resist film 251 and the plurality of pads 241 are disposed on the main surface 201 side (that is, the main surface 231 side). To be noted, the main surface 201 may include a portion of the main surface 231 of the insulating substrate 230 exposed through the solder resist film 251.

In addition, the main surface 202 of the wiring board 220 includes the surface of the solder resist film 252 and the surface of the plurality of pads 242 exposed through the solder resist film 252. That is, the solder resist film 252 and the plurality of pads 242 are disposed on the main surface 202 side (that is, the main surface 232 side). To be noted, the main surface 202 may include a portion of the main surface 232 of the insulating substrate 230 exposed through the solder resist film 252. In the example of FIG. 3, the semiconductor element 210 is disposed on a portion of the main surface 232 of the insulating substrate 230 exposed through the solder resist film 252.

The solder resist films 251 and 252 are each a film formed from a solder resist material. The plurality of pads 241 are each exposed through an opening portion formed in the solder resist film 251. The plurality of pads 242 are each exposed through an opening portion formed in the solder resist film 252. The pads 241 and 242 may be each an SMD pad or an NSMD pad, and are each an SMD pad in the first embodiment.

For example, the semiconductor element 310 mainly includes semiconductor such as a silicon. The wiring board 300 has a main surface 301 serving as an example of a fifth main surface, a main surface 302 serving as an example of a sixth main surface, and an end surface 303 serving as an example of a third end surface. The main surface 302 is a main surface on the opposite side to the main surface 301. The main surface 301 and the main surface 302 are each a mounting surface. The main surface 202 of the wiring board 220 and the main surface 301 of the wiring board 300 oppose each other in the Z direction. The end surface 303 is an outer peripheral surface of the wiring board 300 positioned between the main surfaces 301 and 302 and connected to the main surfaces 301 and 302. The semiconductor element 310 is mounted on the main surface 302.

The wiring board 300 includes an insulating substrate 330. The insulating substrate 330 has a main surface 331 and a main surface 332 on the opposite side to the main surface 331. The material of the insulating substrate 330 is, for example, glass epoxy.

In addition, the wiring board 300 includes a plurality of pads 341 disposed on the main surface 331 of the insulating substrate 330. The plurality of pads 341 are arranged in a peripheral pattern so as to respectively oppose the plurality of pads 242 in the Z direction. The plurality of pads 341 are each a terminal formed from a metal material that is a conductive material, such as copper or gold.

In addition, the wiring board 300 includes a solder resist film 351 disposed around the plurality of pads 341 and on the main surface 331 of the insulating substrate 330, and a solder resist film 352 disposed on the main surface 332 of the insulating substrate 330.

The main surface 301 of the wiring board 300 includes the surface of the solder resist film 351 and the surface of the plurality of pads 341 exposed through the solder resist film 351. That is, the solder resist film 351 and the plurality of pads 341 are disposed on the main surface 301 side (that is, the main surface 331 side). To be noted, the main surface 301 may include a portion of the main surface 331 of the insulating substrate 330 exposed through the solder resist film 351.

In addition, the main surface 302 of the wiring board 300 includes the surface of the solder resist film 352. That is, the solder resist film 352 is disposed on the main surface 302 side (that is, the main surface 332 side). To be noted, the main surface 302 may include a portion of the main surface 332 of the insulating substrate 330 exposed through the solder resist film 352.

The solder resist films 351 and 352 are each a film formed from a solder resist material. The plurality of pads 341 are each exposed through an opening portion formed in the solder resist film 351. The pads 341 may be each an SMD pad or an NSMD pad, and are each an SMD pad in the first embodiment.

The plurality of pads 141 and the plurality of pads 241 are respectively interconnected by a plurality of bonding members 610. The plurality of bonding members 610 are in contact with the pads 141 and 241. The plurality of pads 242 and the plurality of pads 341 are respectively interconnected by a plurality of bonding members 620. The plurality of bonding members 620 are in contact with the pads 242 and 341. To be noted, the bonding members 610 and 620 may or may not overlap with each other in the Z direction.

As described above, the main surface 101 of the wiring board 100 and the main surface 201 of the wiring board 220 are electrically interconnected by being bonded together via the plurality of bonding members 610. The plurality of bonding members 610 are each used for power supply or signal transmission.

In addition, the main surface 202 of the wiring board 220 and the main surface 301 of the wiring board 300 are electrically interconnected by being bonded together via the plurality of bonding members 620. The plurality of bonding members 620 are each used for power supply or signal transmission.

As viewed in the Z direction, the wiring board 100 is larger than each of the wiring board 220 and the wiring board 300. As viewed in the Z direction, the wiring board 220 and the wiring board 300 are approximately equal in size.

The resin reinforcement member 410 is in contact with the main surface 101 of the wiring board 100. In the present embodiment, the resin reinforcement member 410 is in contact with the end surface 203 of the wiring board 220. Further, in the present embodiment, the resin reinforcement member 410 is in contact with the end surface 303 of the wiring board 300. As a result of this, the wiring board 220 and the wiring board 300 are reinforced by the resin reinforcement member 410, and thus the warpage of the wiring board 220 and the warpage of the wiring board 300 are suppressed.

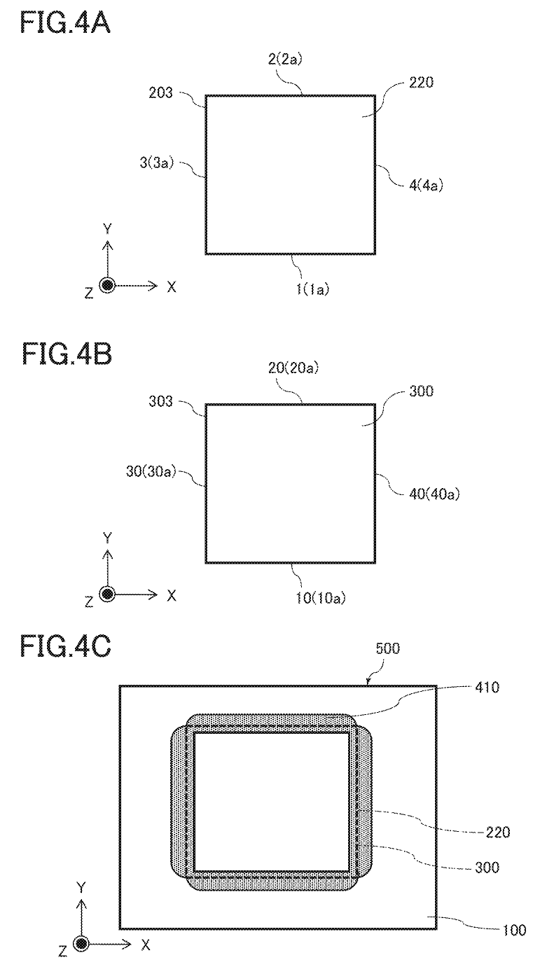

FIG. 4A is a plan view of the wiring board 220 according to the first embodiment, FIG. 4B is a plan view of the wiring board 300 according to the first embodiment, and FIG. 4C is a plan view of the processing module 500 according to the first embodiment. As viewed in the Z direction, the wiring boards 100, 220, and 300 each have a rectangular shape. To be noted, the corner portions of each of the wiring boards 100, 220, and 300 may or may not be chamfered or rounded.

As illustrated in FIG. 4A, the wiring board 220 includes four sides 1 to 4. The end surface 203 includes four end surfaces 1a to 4a respectively corresponding to the four sides 1 to 4. The end surfaces 1a to 4a are each formed in a tapered shape. The sides 1 and 2 are long sides, and the sides 3 and 4 are short sides.

As illustrated in FIG. 4B, the wiring board 300 includes four sides 10 to 40. The end surface 303 includes four end surfaces 10a to 40a respectively corresponding to the four sides 10 to 40. The end surfaces 10a to 40a are each formed in a tapered shape. The sides 10 and 20 are long sides, and the sides 30 and 40 are short sides.

In the processing module 500, the resin reinforcement member 410 is formed to be in contact with the end surface 203 (that is, end surfaces 1a to 4a) of the wiring board 220 and the end surface 303 (that is, end surfaces 10a to 40a) of the wiring board 300. The resin reinforcement member 410 is formed from resin. The resin reinforcement member 410 is a cured product of resin that is thermally or optically cured. As the resin, for example, thermosetting resin or UV-curable resin is used. Depending on the size relationship between the outer shapes of the semiconductor device 200 and the wiring board 300, there is a case where UV light radiated when curing a UV-curable resin does not reach a deep portion in the resin, and thus the resin is partially not cured. Therefore, thermosetting resin is more preferable in that the resin can be more reliably cured by heating the resin in an oven or the like.

The materials constituting the thermosetting resin include epoxy resin, filler, and a curing agent. In some embodiments, the heating temperature for curing the uncured thermosetting resin is lower than the melting point of solder constituting the bonding members 610 and 620, and is also lower than the heat-resistant temperature of the electronic components such as the semiconductor elements 210 and 310. The resin reinforcement member 410 that is a cured product of the thermosetting resin can have a flexural modulus of about several tens [Gpa] to obtain a sufficient reinforcement effect.

In the processing module 500 that is a three-dimensional mounting structure, the resin reinforcement member 410 is formed as follows. To be noted, in the description below, as illustrated in FIG. 2, a direction orthogonal to the main surface 101 of the wiring board 100 will be referred to as a Z direction, and directions along the main surface 101 will be referred to as an X direction and a Y direction. The X direction, the Y direction, and the Z direction are orthogonal to each other. The Z direction also serves as a height direction (that is, thickness direction) of the processing module 500 serving as a three-dimensional mounting structure. The X direction also serves as the longitudinal direction of the resin reinforcement member 410, and the Y direction also serves as the short-side direction of the resin reinforcement member 410.

As illustrated in FIG. 3, the wiring boards 100, 220, and 300 bonded together via the plurality of bonding members 610 and the plurality of bonding members 620 are fixed to each other via the resin reinforcement member 410.

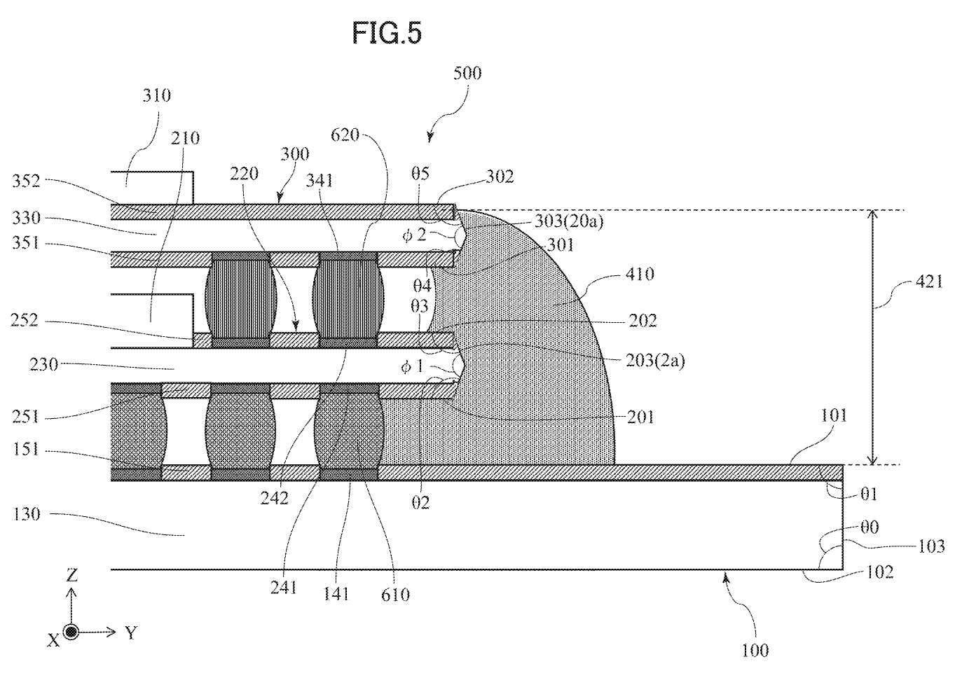

FIG. 5 is a section view of part of the processing module 500 according to the first embodiment. As illustrated in FIG. 5, the resin reinforcement member 410 is in contact with part of the main surface 101 of the wiring board 100, part of the wiring board 220 including the end surface 203, and part of the wiring board 300 including the end surface 303.

The part of the main surface 101 of the wiring board 100 includes part of the surface of the solder resist film 151 of the wiring board 100.

The part of the wiring board 220 including the end surface 203 includes at least part of the end surface 203, and can also include part of the main surface 201 and/or part of the main surface 202. That is, the part of the wiring board 220 including the end surface 203 includes at least part of the end surface 203, and can include part of the surface of the solder resist film 251 and/or part of the surface of the solder resist film 252.

The part of the wiring board 300 including the end surface 303 includes at least part of the end surface 303, and can also include part of the main surface 301 and/or part of the main surface 302. That is, the part of the wiring board 300 including the end surface 303 includes at least part of the end surface 303, and can include part of the surface of the solder resist film 351 and/or part of the surface of the solder resist film 352.

The resin reinforcement member 410 can be in contact with at least bonding members 610 near the sides 1 and 2 (that is, sides 10 and 20) serving as long sides among the outermost bonding members 610 included in the plurality of bonding members 610.

In addition, the resin reinforcement member 410 is formed to a height 421 in the Z direction. In some embodiments, the height 421 is larger than at least a height from the main surface 101 of the wiring board 100 to a center of the wiring board 300 in the thickness direction.

In the first embodiment, the end surface 203 of the wiring board 220 and the end surface 303 of the wiring board 300 are covered by the resin reinforcement member 410. To be noted, the resin reinforcement member 410 may cover the entirety of the end surface 303 of the wiring board 300, and may cover part of the main surface 302.

As described above, since the resin reinforcement member 410 is formed to cover the outer periphery of the mounting structure 510 of the processing module 500 and spread outward from the mounting structure 510 of the processing module 500, an effect of the resin reinforcement member 410 to reinforce the processing module 500 can be obtained. In addition, since the end surface 203 of the wiring board 220 is a tapered surface, the area in contact with the resin reinforcement member 410 is large, and thus the effect of the resin reinforcement member 410 to reinforce the processing module 500 can be obtained sufficiently.

In addition, in a three-dimensional mounting structure, there is a tendency that stress concentrates on the outermost bonding members. In the first embodiment, an angle θ1 formed between the main surface 101 and the end surface 103 on the inner side of the wiring board 100 and/or an angle θ2 formed between the main surface 201 and the end surface 203 on the inner side of the wiring board 220 are each an obtuse angle of 120° or less. The angle θ1 is an example of a first angle, and the angle θ2 is an example of a second angle. In the example of FIG. 5, the angle θ1 is a right angle, and the angle θ2 is an obtuse angle of 120° or less.

As described above, according to the first embodiment, as a result of the angle θ1 and/or the angle θ2 being 120° or less, that is, as a result of the angle θ2 being 120° or less in the example of FIG. 5, concentration of the stress on the outermost bonding members 610 can be suppressed. This is because the rigidity of the tapered part of the wiring board 220 is relatively lower. As a result of this, the influence on the wiring board 220 from the impact when the processing module 500, that is, the camera body 601 is dropped, or from temperature change in the heat cycle or the like caused by the temperature change in the environment or the start or stop of the operation of the digital camera 600 is reduced, and thus the stress acting on the outermost bonding members 610 is reduced. Therefore, the reliability of bonding at the outermost bonding members 610 is improved.

In addition, the angle θ1 and/or the angle θ2 can be an obtuse angle of 105° or less. In the example of FIG. 5, the angle θ2 is an obtuse angle of 105° or less. As a result of this, in the wiring board 100 and/or the wiring board 220, that is, in the wiring board 220 in the example of FIG. 5, a wide region where mounted components such as electronic components can be mounted can be secured.

In more particular embodiments, the angle θ1 and/or the angle θ2 are each an obtuse angle of 100° or less. In the example of FIG. 5, the angle θ2 is an obtuse angle of 100° or less. As a result of this, in the wiring board 100 and/or the wiring board 220, that is, in the wiring board 220 in the example of FIG. 5, a wider region where mounted components such as electronic components can be mounted can be secured.

In addition, the angle θ1 and/or the angle θ2 can be an obtuse angle of 92° or more, and also can be an obtuse angle of 95° or more. In the example of FIG. 5, the angle θ2 is an obtuse angle of 95° or more. As a result of this, the reliability of bonding at the outermost bonding members 610 is further improved.

In addition, in the first embodiment, an angle θ3 formed between the main surface 202 and the end surface 203 on the inner side of the wiring board 220 and/or an angle θ4 formed between the main surface 301 and the end surface 303 on the inner side of the wiring board 300 are each an obtuse angle of 120° or less. The angle θ3 is an example of a third angle, and the angle θ4 is an example of a fourth angle. In the example of FIG. 5, the angle θ3 and the angle θ4 are each an obtuse angle of 120° or less.

As described above, according to the first embodiment, as a result of the angle θ3 and/or the angle θ4 being 120° or less, that is, as a result of the angle θ3 and the angle θ4 being 120° or less in the example of FIG. 5, concentration of the stress on the outermost bonding members 620 can be suppressed. This is because the rigidity of the tapered part of the wiring board 220 and the rigidity of the tapered part of the wiring board 300 are relatively lower. As a result of this, the influence on the wiring boards 220 and 300 from the impact when the processing module 500, that is, the camera body 601 is dropped, or from temperature change in the heat cycle or the like caused by the temperature change in the environment or the start or stop of the operation of the digital camera 600 is reduced, and thus the stress acting on the outermost bonding members 620 is reduced. Therefore, the reliability of bonding at the outermost bonding members 620 is improved.

In addition, the angle θ3 and/or the angle θ4 can be an obtuse angle of 105° or less. In the example of FIG. 5, the angle θ3 and the angle θ4 are each an obtuse angle of 105° or less. As a result of this, in the wiring board 220 and/or the wiring board 300, that is, in the wiring board 220 and the wiring board 300 in the example of FIG. 5, a wide region where mounted components such as electronic components can be mounted can be secured.

In more particular embodiments, the angle θ3 and/or the angle θ4 are each an obtuse angle of 100° or less. In the example of FIG. 5, the angle θ3 and the angle θ4 are each an obtuse angle of 100° or less. As a result of this, in the wiring board 220 and/or the wiring board 300, that is, in the wiring board 220 and the wiring board 300 in the example of FIG. 5, a wider region where mounted components such as electronic components can be mounted can be secured.

In addition, the angle θ3 and/or the angle θ4 can be an obtuse angle of 92° or more, and also can be an obtuse angle of 95° or more. In the example of FIG. 5, the angle θ3 and the angle θ4 are each an obtuse angle of 95° or more. As a result of this, the reliability of bonding at the outermost bonding members 620 is further improved.

From the viewpoint of the reliability of bonding at the outermost bonding members 610, an angle θ0 formed between the main surface 102 and the end surface 103 on the inner side of the wiring board 100 and/or the angle θ3 formed between the main surface 202 and the end surface 203 on the inner side of the wiring board 220 can be an obtuse angle of 120° or less.

In the example illustrated in FIG. 5, the angle θ3 in the wiring board 220 is an obtuse angle of 120° or less. As a result of this, the stress on the outermost bonding members 610 is further reduced, and the reliability of the bonding at the outermost bonding members 610 is further improved.

In addition, from the viewpoint of the reliability of bonding at the outermost bonding members 620, the angle θ2 formed between the main surface 201 and the end surface 203 on the inner side of the wiring board 220 and/or an angle θ5 formed between the main surface 302 and the end surface 303 on the inner side of the wiring board 300 can be an obtuse angle of 120° or less.

In the example illustrated in FIG. 5, the angle θ2 in the wiring board 220 is an obtuse angle of 120° or less, and the angle θ5 in the wiring board 300 is an obtuse angle of 120° or less. As a result of this, the stress on the outermost bonding members 620 is further reduced, and the reliability of the bonding at the outermost bonding members 620 is further improved.

In addition, from the viewpoint of the reliability of bonding at the outermost bonding members 610, the angle formed between a portion of the end surface 103 connected to the main surface 101 and a portion of the end surface 103 connected to the main surface 102 on the inner side of the wiring board 100 and/or an angle formed between a portion of the end surface 203 connected to the main surface 201 and a portion of the end surface 203 connected to the main surface 202 on the inner side of the wiring board 220 can be an obtuse angle of 120° or more.

In addition, from the viewpoint of the reliability of bonding at the outermost bonding members 620, the angle formed between a portion of the end surface 203 connected to the main surface 201 and a portion of the end surface 203 connected to the main surface 202 on the inner side of the wiring board 220 and/or an angle formed between a portion of the end surface 303 connected to the main surface 301 and a portion of the end surface 303 connected to the main surface 302 on the inner side of the wiring board 300 can be an obtuse angle of 120° or more.

In the example of FIG. 5, the angle θ2 formed between the portion of the end surface 203 connected to the main surface 201 and the main surface 201 on the inner side of the wiring board 220 and the angle θ3 formed between the portion of the end surface 203 connected to the main surface 202 and the main surface 202 on the inner side of the wiring board 220 are each an obtuse angle of 120° or less. Further, an angle φ1 formed between the portion of the end surface 203 connected to the main surface 201 and the portion of the end surface 203 connected to the main surface 202 on the inner side of the wiring board 220 is an obtuse angle of 120° or more. As a result of this, the reliability of the bonding at the outermost bonding members 610 and the reliability of the bonding at the outermost bonding members 620 are further improved. In the case where the angle φ1 is an obtuse angle of 120° or more, one of the angles θ2 and θ3 does not have to be an obtuse angle of 120° or less, and may be a right angle, an acute angle, or an obtuse angle of 120° or more.

In addition, the angles θ2 and θ3 can be each an obtuse angle of 105° or less, and in this case, the angle φ1 can be 150° or more. In addition, the angles θ2 and θ3 can be each an obtuse angle of 100° or less, and in this case, the angle φ1 can be 160° or more. In addition, the angles θ2 and θ3 can be each an obtuse angle of 95° or more, and in this case, the angle φ1 can be 170° or less.

In addition, in the example of FIG. 5, the angle θ4 formed between the portion of the end surface 303 connected to the main surface 301 and the main surface 301 on the inner side of the wiring board 300 and the angle θ5 formed between the portion of the end surface 303 connected to the main surface 302 and the main surface 302 on the inner side of the wiring board 300 are each an obtuse angle of 120° or less. Further, an angle φ2 formed between the portion of the end surface 303 connected to the main surface 301 and the portion of the end surface 303 connected to the main surface 302 on the inner side of the wiring board 300 is an obtuse angle of 120° or more. As a result of this, the reliability of the bonding at the outermost bonding members 620 is further improved. In the case where the angle φ2 is an obtuse angle of 120° or more, one of the angles θ4 and θ5 does not have to be an obtuse angle of 120° or less, and may be a right angle, an acute angle, or an obtuse angle of 120° or more.

In addition, the angles θ4 and θ5 can be each an obtuse angle of 105° or less, and in this case, the angle φ2 can be 150° or more. In addition, the angles θ4 and θ5 can be each an obtuse angle of 100° or less, and in this case, the angle φ2 can be 160° or more. In addition, the angles θ4 and θ5 can be each an obtuse angle of 95° or more, and in this case, the angle φ2 can be 170° or less.

In addition, in the first embodiment, the resin reinforcement member 410 is in contact with the main surface 101 of the wiring board 100 and the end surface 203 of the wiring board 220. Therefore, the force acting on the end surface 203 of the wiring board 220 due to the impact when the camera body 601 is dropped or temperature change in the heat cycle or the like caused by the temperature change in the environment or the start or stop of the operation of the digital camera 600 can be distributed to the Z direction orthogonal to the main surface 101 of the wiring board 100 and the X direction and the Y direction parallel to the main surface 101, thus the deformation of the wiring board 220 is suppressed, the stress on the bonding members 610 is further reduced, and the reliability of the bonding at the bonding members 610 is further improved.

In addition, in the first embodiment, the resin reinforcement member 410 is in contact with the main surface 101 of the wiring board 100 and the end surface 303 of the wiring board 300. Therefore, the force acting on the end surface 303 of the wiring board 300 due to the impact when the camera body 601 is dropped or temperature change in the heat cycle or the like caused by the temperature change in the environment or the start or stop of the operation of the digital camera 600 can be distributed to the Z direction orthogonal to the main surface 101 of the wiring board 100 and the X direction and the Y direction parallel to the main surface 101, thus the deformation of the wiring board 300 is suppressed, the stress on the bonding members 620 is further reduced, and the reliability of the bonding at the bonding members 620 is further improved.

In some embodiments, the thickness of at least one of the wiring boards 100, 220, and 300 is 0.1 mm or more and 10 mm or less. In more particular embodiments, the thickness of at least one of the wiring boards 100, 220, and 300 is 5 mm or less. In even more particular embodiments, the thickness of at least one of the wiring boards 100, 220, and 300 is 0.4 mm or more and 2 mm or less.

In some embodiments, part of the main surface serving as a standard for evaluation of an angle of an end surface of the wiring board is part of the main surface whose distance from the end surface is equal to or less than the thickness of the wiring board. For example, in the case where the thickness of the wiring board is 1 mm, the angle formed between the end surface and part of the main surface that is 1 mm or less from the end surface may be evaluated.

To be noted, although a case where the wiring boards 100, 220, and 300 are each a rigid board has been described in the first embodiment, the configuration is not limited to this. For example, at least one of the wiring boards 100, 220, and 300 may be a flexible board.

In addition, although a case where the substrate of each of the wiring board 100 serving as a first electric board, the wiring board 220 serving as a second electric board, and the wiring board 300 serving as a third electric board is resin such as glass epoxy has been described in the first embodiment, the configuration is not limited to this. For example, the substrate of at least one of the first electric board, the second electric board, and the third electric board may be a semiconductor substrate (single crystal, polycrystal, simple, or compound), a ceramic substrate, a glass substrate, or a metal substrate. The electric board may be formed by adding an electrode, wiring, an active element, a passive element, an insulator, and the like to a semiconductor substrate, a glass substrate, or a metal substrate. In addition, for example, at least one of the first electric board, the second electric board, and the third electric board may be a board formed by bonding layers of different kinds such as a multilayer board (for example, a board in which an insulating layer is provided on a semiconductor layer or a board in which semiconductor layers of different kinds are laminated).

### Second Embodiment

An electric module according to a second embodiment will be described. In the description below, it is assumed that elements denoted by the same reference signs as in the embodiment described above have substantially the same configurations and functions as those described in the embodiment described above unless described otherwise, and part different from the embodiment described above will be mainly described.

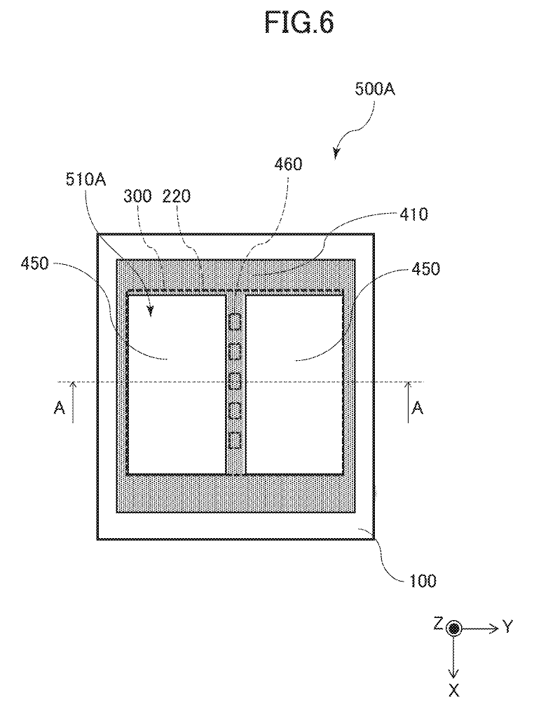

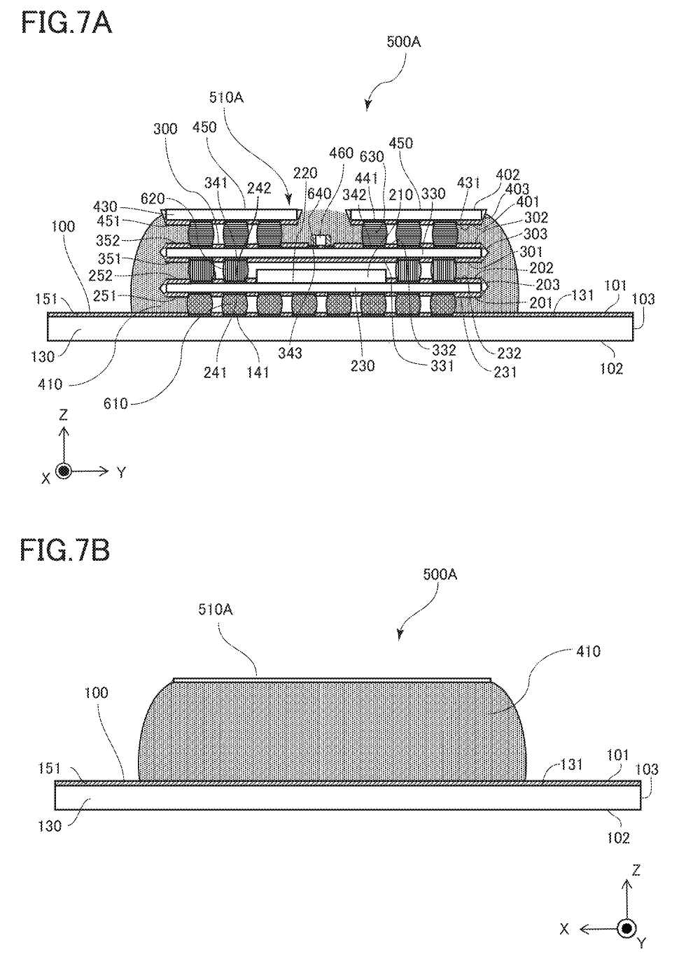

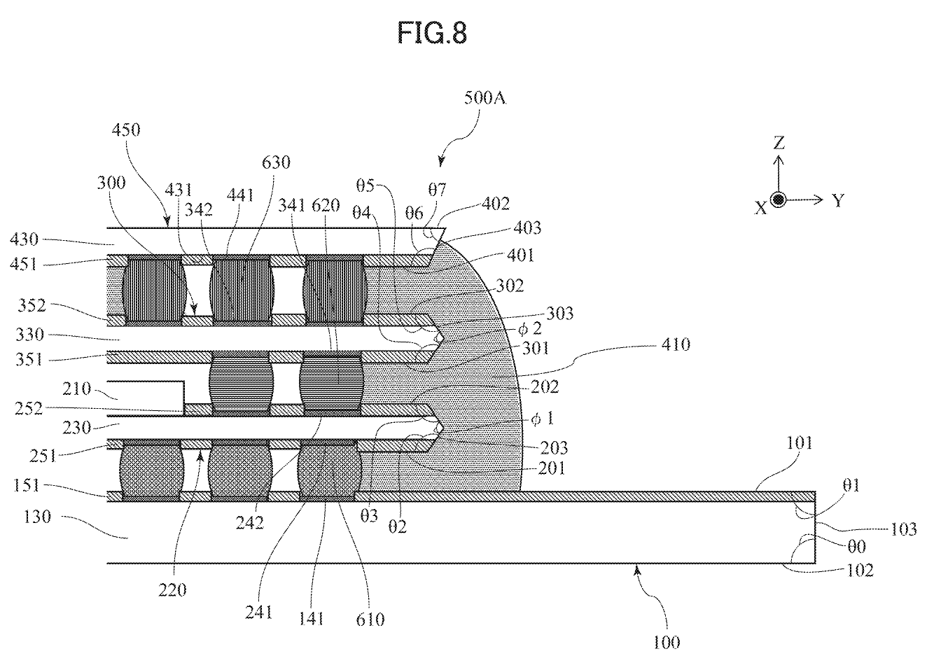

FIG. 6 is a plan view of a processing module 500A according to the second embodiment. FIG. 7A is a section view of the processing module 500A according to the second embodiment. FIG. 7A illustrates a cross-section of the processing module 500A taken along a plane A-A illustrated in FIG. 6. The plane A-A is a virtual plane parallel to the YZ plane. FIG. 7B is a side view of the processing module 500A according to the second embodiment. FIG. 7B illustrates the processing module 500A as viewed in the -Y direction. FIG. 8 is a section view of part of the processing module 500A according to the second embodiment.

The camera body in the second embodiment has a configuration in which the processing module 500 in the camera body 601 illustrated in FIG. 1 is replaced by the processing module 500A illustrated in FIGS. 6 to 8.

The processing module 500A includes the wiring board 100, a mounting structure 510A mounted on the wiring board 100, and the resin reinforcement member 410 formed from resin and surrounding the mounting structure 510A. The mounting structure 510A is a three-dimensionally-mounted structure.

The mounting structure 510A includes the wiring board 220 bonded onto the wiring board 100 via the plurality of bonding members 610, the semiconductor element 210 mounted on the wiring board 220, the wiring board 300 bonded onto the wiring board 220 via the plurality of bonding members 620, a plurality of plates 450 bonded onto the wiring board 300 via a plurality of bonding members 630, and a plurality of electronic components 460 bonded onto the wiring board 300 via a plurality of bonding members 640.

The plurality of bonding members 610, 620, 630, and 640 are each formed from a conductive member such as solder. The plurality of bonding members 630 are each an example of a third bonding member.

The plate 450 has a main surface 401 serving as an example of a seventh main surface, a main surface 402 serving as an example of an eighth main surface, and an end surface 403 serving as an example of a fourth end surface. The main surface 402 is a main surface on the opposite side to the main surface 401. The main surface 302 of the wiring board 300 and the main surface 401 of the plate 450 oppose each other in the Z direction. The end surface 403 is an outer peripheral surface of the plate 450 positioned between the main surfaces 401 and 402 and connected to the main surfaces 401 and 402.

The plate 450 includes a semiconductor chip 430, a plurality of pads 441 disposed on a main surface 431 of the semiconductor chip 430, and a solder resist film 451 disposed around the plurality of pads 441 and on the main surface 431 of the semiconductor chip 430. The plate 450 is, for example, a memory-packaged plate.

The main surface 401 of the plate 450 includes a surface of the solder resist film 451 and the surface of the plurality of pads 441 exposed through the solder resist film 451. That is, the solder resist film 451 and the plurality of pads 441 are disposed on the main surface 401 side (that is, the main surface 431 side). To be noted, the main surface 401 may include part of the main surface 431 of the semiconductor chip 430 exposed through the solder resist film 451.

The plurality of pads 441 may be arranged in a lattice pattern, that is, in a matrix pattern, a peripheral pattern, or a staggered pattern. The plurality of pads 441 are each a terminal formed from a metal material that is a conductive material, such as copper or gold.

The material of the semiconductor chip 430 is, for example, silicon. The solder resist film 451 is a film formed from a solder resist material. The plurality of pads 441 are each exposed through an opening portion provided in the solder resist film 451. The pad 441 may be an SMD pad or an NSMD pad, and is an SMD pad in the second embodiment.

A plurality of electronic components 460 are mounted on the main surface 302 of the wiring board 300. For example, the plurality of electronic components 460 are each a chip component such as a capacitor component or a resistor component.

The wiring board 300 includes a plurality of pads 342 and a plurality of pads 343 disposed on a main surface 332 of an insulating substrate 330. The plurality of pads 342 are arranged to respectively oppose the plurality of pads 441 in the Z direction. The plurality of pads 342 and 343 are each a terminal formed from a metal material that is a conductive material, such as copper or gold.

In addition, the wiring board 300 includes a solder resist film 352 disposed around the plurality of pads 342 and 343 and on the main surface 332 of the insulating substrate 330.

The main surface 302 of the wiring board 300 includes the surface of the solder resist film 352 and the surface of the plurality of pads 342 and 343 exposed through the solder resist film 352. That is, the solder resist film 352 and the plurality of pads 342 and 343 are disposed on the main surface 302 side (that is, the main surface 332 side). To be noted, the main surface 302 may include part of the main surface 332 of the insulating substrate 330 exposed through the solder resist film 352.

The plurality of pads 342 and 343 are each exposed through an opening portion provided in the solder resist film 352. The pads 342 and 343 each may be an SMD pad or an NSMD pad, and are each an SMD pad in the second embodiment.

The plurality of pads 342 are respectively bonded to the plurality of pads 441 via the plurality of bonding members 630. The bonding members 630 are in contact with the pads 342 and 441. As described above, the main surface 302 of the wiring board 300 and the main surface 401 of the plate 450 are bonded together via the plurality of bonding members 630, and are thus electrically interconnected. The plurality of bonding members 630 are each used for power supply or signal transmission.

In addition, each electrode of each of the plurality of electronic components 460 is bonded to corresponding one of the plurality of pads 343 via corresponding one of the bonding members 640, and is thus electrically connected to the main surface 302 of the wiring board 300.

The resin reinforcement member 410 is in contact with the main surface 101 of the wiring board 100. In the present embodiment, the resin reinforcement member 410 is in contact with the end surface 203 of the wiring board 220. Further, in the present embodiment, the resin reinforcement member 410 is in contact with the end surface 303 of the wiring board 300. Further, in the present embodiment, the resin reinforcement member 410 is in contact with the end surface 403 of the plate 450. As a result of this, the wiring board 220, the wiring board 300, and the plate 450 are reinforced by the resin reinforcement member 410, and thus the warpage of the wiring board 220, the warpage of the wiring board 300, and the warpage of the plate 450 are suppressed.

In addition, in the second embodiment, an angle θ5 formed between the main surface 302 and the end surface 103 on the inner side of the wiring board 300 and/or an angle θ6 formed between the main surface 401 and the end surface 403 on the inner side of the plate 450 are each an obtuse angle of 120° or less. The angle θ5 is an example of a fifth angle, and the angle θ6 is an example of a sixth angle. In the example of FIG. 8, the angle θ5 and the angle θ6 are each an obtuse angle of 120° or less.

As described above, according to the second embodiment, as a result of the angle θ5 and/or the angle θ6 being 120° or less, that is, as a result of the angle θ5 and the angle θ6 being 120° or less in the example of FIG. 8, concentration of the stress on the outermost bonding members 630 can be suppressed. This is because the rigidity of the tapered part of the wiring board 300 and the rigidity of the tapered part of the plate 450 are relatively lower. As a result of this, the influence on the wiring board 300 and the plate 450 from the impact when the processing module 500A, that is, the camera body 601 is dropped, or from temperature change in the heat cycle or the like caused by the temperature change in the environment or the start or stop of the operation of the digital camera 600 is reduced, and thus the stress acting on the outermost bonding members 630 is reduced. Therefore, the reliability of bonding at the outermost bonding members 630 is improved.

In addition, the angle θ5 and/or the angle θ6 can be an obtuse angle of 105° or less. In the example of FIG. 8, the angle θ5 and the angle θ6 are each an obtuse angle of 105° or less. As a result of this, in the wiring board 300, a wide region where mounted components such as the electronic components 460 can be mounted can be secured.

In more particular embodiments, the angle θ5 and/or the angle θ6 are each an obtuse angle of 100° or less. In the example of FIG. 8, the angle θ5 and the angle θ6 are each an obtuse angle of 100° or less. As a result of this, in the wiring board 300, a wider region where mounted components such as the electronic components 460 can be mounted can be secured.

In addition, the angle θ5 and/or the angle θ6 can be an obtuse angle of 92° or more, and also can be an obtuse angle of 95° or more. In the example of FIG. 8, the angle θ5 and the angle θ6 are each an obtuse angle of 95° or more. As a result of this, the reliability of bonding at the outermost bonding members 630 is further improved.

From the viewpoint of the reliability of bonding at the outermost bonding members 630, the angle θ4 formed between the main surface 301 and the end surface 303 on the inner side of the wiring board 300 can be an obtuse angle of 120° or less.

In the example illustrated in FIG. 8, the angle θ4 in the wiring board 300 is an obtuse angle of 120° or less. As a result of this, the stress on the outermost bonding members 630 is further reduced, and the reliability of the bonding at the outermost bonding members 630 is further improved. In the example illustrated in FIG. 8, an angle θ7 is an acute angle. As a result of this, a large area can be secured for part of the end surface 403 that forms an obtuse angle θ6 with the main surface 401, and thus the reliability of the bonding at the outermost bonding members 630 is further improved. To be noted, the angle θ7 formed between the main surface 402 and part of the end surface 403 connected to the main surface 402 on the inner side of the plate 450 can be also a right angle or an obtuse angle of 120°or less.

In addition, from the viewpoint of the reliability of bonding at the outermost bonding members 630, the angle formed between a portion of the end surface 303 connected to the main surface 301 and a portion of the end surface 303 connected to the main surface 302 on the inner side of the wiring board 300 and/or the angle formed between a portion of the end surface 403 connected to the main surface 401 and a portion of the end surface 403 connected to the main surface 402 on the inner side of the plate 450 can be an obtuse angle of 120° or more.

In the example of FIG. 8, the angle θ4 formed between the portion of the end surface 303 connected to the main surface 301 and the main surface 301 and the angle θ5 formed between the portion of the end surface 303 connected to the main surface 302 and the main surface 302 on the inner side of the wiring board 300 are each an obtuse angle of 120° or less. Further, an angle φ2 formed between the portion of the end surface 303 connected to the main surface 301 and the portion of the end surface 303 connected to the main surface 302 on the inner side of the wiring board 300 is an obtuse angle of 120° or more. As a result of this, the reliability of the bonding at the outermost bonding members 630 and the reliability of the bonding at the outermost bonding members 620 are further improved. In the case where the angle φ2 is an obtuse angle of 120° or more, one of the angles θ4 and θ5 does not have to be an obtuse angle of 120° or less, and may be a right angle, an acute angle, or an obtuse angle of 120° or more.

In addition, the angles θ4 and θ5 can be each an obtuse angle of 105° or less, and in this case, the angle φ2 can be 150° or more. In addition, the angles θ4 and θ5 can be each an obtuse angle of 100° or less, and in this case, the angle φ2 can be 160° or more. In addition, the angles θ4 and θ5 can be each an obtuse angle of 95° or more, and in this case, the angle φ2 can be 170° or less.

In addition, in the second embodiment, the resin reinforcement member 410 is in contact with the main surface 101 of the wiring board 100, the end surface 203 of the wiring board 220, the end surface 303 of the wiring board 300, and the end surface 403 of the plate 450. Therefore, the force acting on the end surface 203 of the wiring board 220, the end surface 303 of the wiring board 300, and the end surface 403 of the plate 450 due to the impact when the camera body 601 is dropped or temperature change in the heat cycle or the like caused by the temperature change in the environment or the start or stop of the operation of the digital camera 600 can be distributed to the Z direction orthogonal to the main surface 101 of the wiring board 100 and the X direction and the Y direction parallel to the main surface 101 of the wiring board 100, thus the deformation of the wiring board 220, the wiring board 300, and the plate 450 is suppressed, the stress on the bonding members 610, 620, and 630 is further reduced, and the reliability of the bonding at the bonding members 610, 620, and 630 is further improved.

In some embodiments, the thickness of the plate 450 is 0.1 mm or more and 10 mm or less. In more particular embodiments, the thickness of the plate 450 is 5 mm or less. In even more particular embodiments, the thickness of the plate 450 is 0.4 mm or more and 2 mm or less.

To be noted, although a case where the plate 450 serving as a fourth board includes the semiconductor chip 430 has been described in the second embodiment, the configuration is not limited to this. For example, the fourth board may be a wiring board including an insulating substrate, a semiconductor substrate (single crystal, polycrystal, simple, or compound), a glass plate, or a metal plate. In addition, for example, the plate may be a board formed by bonding layers of different kinds such as a multilayer board (for example, a board in which an insulating layer is provided on a semiconductor layer or a board in which semiconductor layers of different kinds are laminated).

### Third Embodiment

An electric module according to a third embodiment will be described. In the description below, it is assumed that elements denoted by the same reference signs as in the embodiments described above have substantially the same configurations and functions as those described in the embodiments described above unless described otherwise, and part different from the embodiments described above will be mainly described.

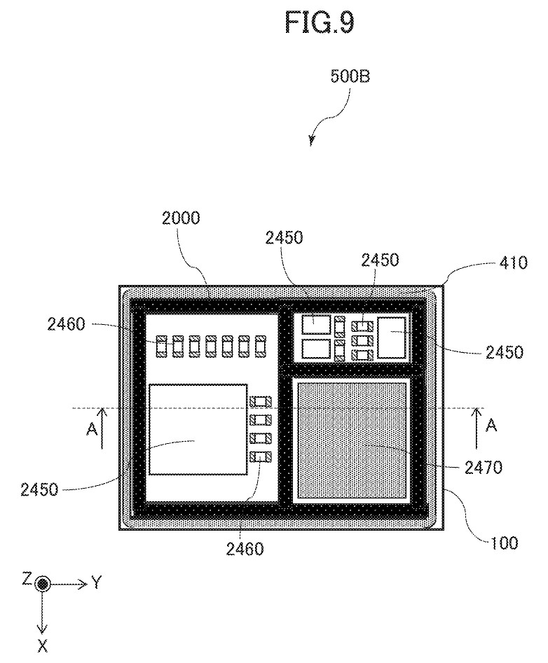

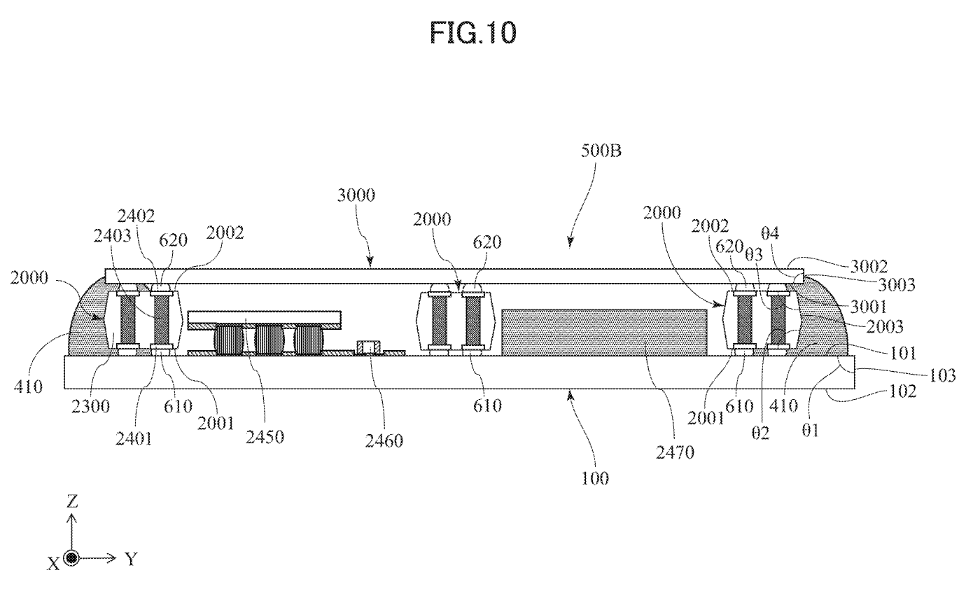

FIG. 9 is a plan view of a processing module 500B according to the third embodiment. FIG. 10 is a section view of the processing module 500B according to the third embodiment. FIG. 10 illustrates a cross-section of the processing module 500B taken along a plane A-A illustrated in FIG. 9. The plane A-A is a virtual plane parallel to the YZ plane.

The camera body in the third embodiment has a configuration in which the processing module 500 in the camera body 601 illustrated in FIG. 1 is replaced by the processing module 500B illustrated in FIGS. 9 and 10.

The processing module 500B includes the wiring board 100, a wiring board 3000, and a wiring member 2000 electrically interconnecting the wiring board 100 and the wiring board 3000. To be noted, in FIG. 9, illustration of the wiring board 3000 is omitted.

The wiring board 100 is an example of a first electric board. The wiring member 2000 is an example of a second electric board. The wiring board 3000 is an example of a third electric board. The wiring board 100 is a rigid board. The wiring member 2000 is a rigid board, and is a wiring board smaller than the wiring board 100 and the wiring board 3000. The wiring board 3000 is a rigid board. Unillustrated semiconductor elements, chip components, and the like are mounted on the wiring board 300.

The wiring member 2000 is disposed between the wiring board 100 and the wiring board 3000. The wiring board 100 and the wiring board 3000 are laminated with the wiring member 2000 therebetween. That is, the processing module 500B is formed as a three-dimensional mounting structure as a result of the wiring board 100 and the wiring board 3000 being laminated in the Z direction with the wiring member 2000 therebetween. The processing module 500B includes the resin reinforcement member 410 surrounding the wiring member 2000.

The wiring board 100 and the wiring member 2000 are bonded together via the plurality of bonding members 610. The wiring member 2000 and the wiring board 3000 are bonded together via the plurality of bonding members 620. The plurality of bonding members 610 are each an example of a first bonding member. The plurality of bonding members 620 are each an example of a second bonding member. The plurality of bonding members 610 are each formed from a conductive member such as solder. The plurality of bonding members 620 are each formed from a conductive member such as solder.

The wiring member 2000 is disposed between the wiring board 100 and the wiring board 3000, and is used for electrical connection and mechanical connection between the wiring board 100 and the wiring board 3000. In addition, the wiring member 2000 also functions as a spacer that maintains the gap between the wiring board 100 and the wiring board 3000. A gap is provided between the wiring board 100 and the wiring board 3000. The processing module 500B includes, as a plurality of mounted components provided in this gap, a battery 2470, a plurality of wiring boards 2450, and a plurality of electronic components 2460.

For example, the plurality of wiring boards 2450 are each a memory-packaged plate. A solder resist film (not illustrated) is provided on the main surface of each of the plurality of wiring boards 2450, and a pad is exposed through an opening portion provided in the solder resist film. The plurality of electronic components 2460 are, for example, chip components such as capacitor components and resistor components.

The wiring member 2000 has a main surface 2001 serving as an example of a third main surface, a main surface 2002 serving as an example of a fourth main surface, and an end surface 2003 serving as an example of a second end surface. The main surface 2002 is a main surface on the opposite side to the main surface 2001. The main surface 101 of the wiring board 100 and the main surface 2001 of the wiring member 2000 oppose each other in the Z direction. The end surface 2003 is an outer peripheral surface of the wiring member 2000 positioned between the main surface 2001 and the main surface 2002 and connected to the main surface 2001 and the main surface 2002.

The wiring member 2000 includes an insulating substrate 2300. The material of the insulating substrate 2300 is, for example, glass epoxy.

The wiring member 2000 includes a plurality of via conductors 2403 disposed on the insulating substrate 2300. The plurality of via conductors 2403 are each a conductor. A plurality of through holes are provided in the insulating substrate 2300, and the plurality of via conductors 2403 are each a through hole conductor disposed in corresponding one of the plurality of through holes.

In addition, the wiring member 2000 includes a plurality of pads 2401 constituting part of the main surface 2001 and a plurality of pads 2402 constituting part of the main surface 2002. The plurality of pads 2401 are respectively connected to the plurality of pads 2402 via the plurality of via conductors 2403. The plurality of pads 2401, the plurality of pads 2402, and the plurality of via conductors 2403 are each formed from a metal material that is a conductive material, such as copper or gold.

The wiring board 3000 has a main surface 3001 serving as an example of a fifth main surface, a main surface 3002 serving as an example of a sixth main surface, and an end surface 3003 serving as an example of a third end surface. The main surface 3002 is a main surface on the opposite side to the main surface 3001. The main surface 2002 of the wiring member 2000 and the main surface 3001 of the wiring board 3000 oppose each other in the Z direction. The end surface 3003 is an outer peripheral surface of the wiring board 3000 positioned between the main surfaces 3001 and 3002 and connected to the main surfaces 3001 and 3002.

The wiring board 3000 includes a plurality of unillustrated pads constituting part of the main surface 3001. The plurality of pads are each formed from a metal material that is a conductive material, such as copper or gold.

The plurality of pads 2401 are each bonded to corresponding one of the pads on the main surface 101 of the wiring board 100 via corresponding one of the bonding members 610. The plurality of pads 2402 are each bonded to corresponding one of the pads on the main surface 3001 of the wiring board 3000 via corresponding one of the bonding members 620. To be noted, the bonding members 610 and the bonding members 620 may or may not overlap with each other in the Z direction.

As described above, the main surface 101 of the wiring board 100 and the main surface 2001 of the wiring member 2000 are electrically interconnected by being bonded together via the plurality of bonding members 610. The plurality of bonding members 610 are each used for power supply or signal transmission.

In addition, the main surface 2002 of the wiring member 2000 and the main surface 3001 of the wiring board 3000 are electrically interconnected by being bonded together via the plurality of bonding members 620. The plurality of bonding members 620 are each used for power supply or signal transmission.

The resin reinforcement member 410 is in contact with the main surface 101 of the wiring board 100. In the present embodiment, the resin reinforcement member 410 is in contact with the end surface 2003 of the wiring member 2000. Further, in the present embodiment, the resin reinforcement member 410 is in contact with the end surface 3003 of the wiring board 3000. As a result of this, the wiring member 2000 and the wiring board 3000 are reinforced by the resin reinforcement member 410, and thus the warpage of the wiring member 2000 and the warpage of the wiring board 3000 are suppressed.

In the third embodiment, an angle θ1 formed between the main surface 101 and the end surface 103 on the inner side of the wiring board 100 and/or an angle θ2 formed between the main surface 2001 and the end surface 2003 on the inner side of the wiring member 2000 are each an obtuse angle of 120° or less. The angle θ1 is an example of a first angle, and the angle θ2 is an example of a second angle. In the example of FIG. 10, the angle θ1 is a right angle, and the angle θ2 is an obtuse angle of 120° or less.

As described above, according to the third embodiment, as a result of the angle θ1 and/or the angle θ2 being 120° or less, that is, as a result of the angle θ2 being 120° or less in the example of FIG. 10, concentration of the stress on the outermost bonding members 610 can be suppressed. This is because the rigidity of the tapered part of the wiring member 2000 is relatively lower. As a result of this, the influence on the wiring member 2000 from the impact when the processing module 500B, that is, the camera body 601 is dropped, or from temperature change in the heat cycle or the like caused by the temperature change in the environment or the start or stop of the operation of the digital camera 600 is reduced, and thus the stress acting on the outermost bonding members 610 is reduced. Therefore, the reliability of bonding at the outermost bonding members 610 is improved.

In addition, the angle θ1 and/or the angle θ2 can be an obtuse angle of 105° or less. In the example of FIG. 10, the angle θ2 is an obtuse angle of 105° or less. In more particular embodiments, the angle θ1 and/or the angle θ2 are each an obtuse angle of 100° or less. In the example of FIG. 10, the angle θ2 is an obtuse angle of 100° or less.

In addition, the angle θ1 and/or the angle θ2 can be an obtuse angle of 92° or more, and also can be an obtuse angle of 95° or more. In the example of FIG. 10, the angle θ1 is an obtuse angle of 95° or more. As a result of this, the reliability of bonding at the outermost bonding members 610 is further improved.

In addition, in the third embodiment, an angle θ3 formed between the main surface 2002 and the end surface 2003 on the inner side of the wiring member 2000 and/or an angle θ4 formed between the main surface 3001 and the end surface 3003 on the inner side of the wiring board 3000 are each an obtuse angle of 120° or less. The angle θ3 is an example of a third angle, and the angle θ4 is an example of a fourth angle. In the example of FIG. 10, the angle θ3 is an obtuse angle of 120° or less.

As described above, according to the third embodiment, as a result of the angle θ3 and/or the angle θ4 being 120° or less, that is, as a result of the angle θ3 being 120° or less in the example of FIG. 10, concentration of the stress on the outermost bonding members 620 can be suppressed. This is because the rigidity of the tapered part of the wiring member 2000 is relatively lower. As a result of this, the influence on the wiring member 2000 from the impact when the processing module 500B, that is, the camera body 601 is dropped, or from temperature change in the heat cycle or the like caused by the temperature change in the environment or the start or stop of the operation of the digital camera 600 is reduced, and thus the stress acting on the outermost bonding members 620 is reduced. Therefore, the reliability of bonding at the outermost bonding members 620 is improved.

In addition, the angle θ3 and/or the angle θ4 can be an obtuse angle of 105° or less. In the example of FIG. 10, the angle θ3 is an obtuse angle of 105° or less. In more particular embodiments, the angle θ3 and/or the angle θ4 are each an obtuse angle of 100° or less. In the example of FIG. 10, the angle θ3 is an obtuse angle of 100° or less.

In addition, the angle θ3 and/or the angle θ4 can be an obtuse angle of 92° or more, and also can be an obtuse angle of 95° or more. In the example of FIG. 10, the angle θ3 is an obtuse angle of 95° or more. As a result of this, the reliability of bonding at the outermost bonding members 620 is further improved.

In addition, in the third embodiment, the resin reinforcement member 410 is in contact with the main surface 101 of the wiring board 100 and the end surface 2003 of the wiring member 2000. Therefore, the force acting on the end surface 2003 of the wiring member 2000 due to the impact when the camera body 601 is dropped or temperature change in the heat cycle or the like caused by the temperature change in the environment or the start or stop of the operation of the digital camera 600 can be distributed to the Z direction orthogonal to the main surface 101 of the wiring board 100 and the X direction and the Y direction parallel to the main surface 101, thus the deformation of the wiring member 2000 is suppressed, the stress on the bonding members 610 is further reduced, and the reliability of the bonding at the bonding members 610 is further improved.

In addition, in the third embodiment, the resin reinforcement member 410 is in contact with the main surface 101 of the wiring board 100 and the end surface 3003 of the wiring board 3000. Therefore, the force acting on the end surface 3003 of the wiring board 3000 due to the impact when the camera body 601 is dropped or temperature change in the heat cycle or the like caused by the temperature change in the environment or the start or stop of the operation of the digital camera 600 can be distributed to the Z direction orthogonal to the main surface 101 of the wiring board 100 and the X direction and the Y direction parallel to the main surface 101, thus the deformation of the wiring board 3000 is suppressed, the stress on the bonding members 620 is further reduced, and the reliability of the bonding at the bonding members 620 is further improved.

In some embodiments, the thickness of at least one of the wiring board 100, the wiring member 2000, and the wiring board 3000 is 0.1 mm or more and 10 mm or less. In more particular embodiments, the thickness of at least one of the wiring board 100, the wiring member 2000, and the wiring board 3000 is 5 mm or less. In even more particular embodiments, the thickness of at least one of the wiring board 100, the wiring member 2000, and the wiring board 3000 is 0.4 mm or more and 2 mm or less.

To be noted, the plurality of wiring members 2000 may be a combination of rectangles of different lengths in view of reduction of cost and reduction of waste of wiring boards during manufacture.

In addition, although the processing modules 500 to 500B have been described as examples of an electric module in the first to third embodiments, the configuration is not limited to this, and a configuration similar to that of the processing modules of the first to third embodiments can be also applied to electric modules other than processing modules. For example, a configuration similar to that of the processing modules of the first to third embodiments can be also applied to the sensor module 650.

### Fourth Embodiment

An electric module according to a fourth embodiment will be described. In the description below, it is assumed that elements denoted by the same reference signs as in the embodiments described above have substantially the same configurations and functions as those described in the embodiments described above unless described otherwise, and part different from the embodiments described above will be mainly described.

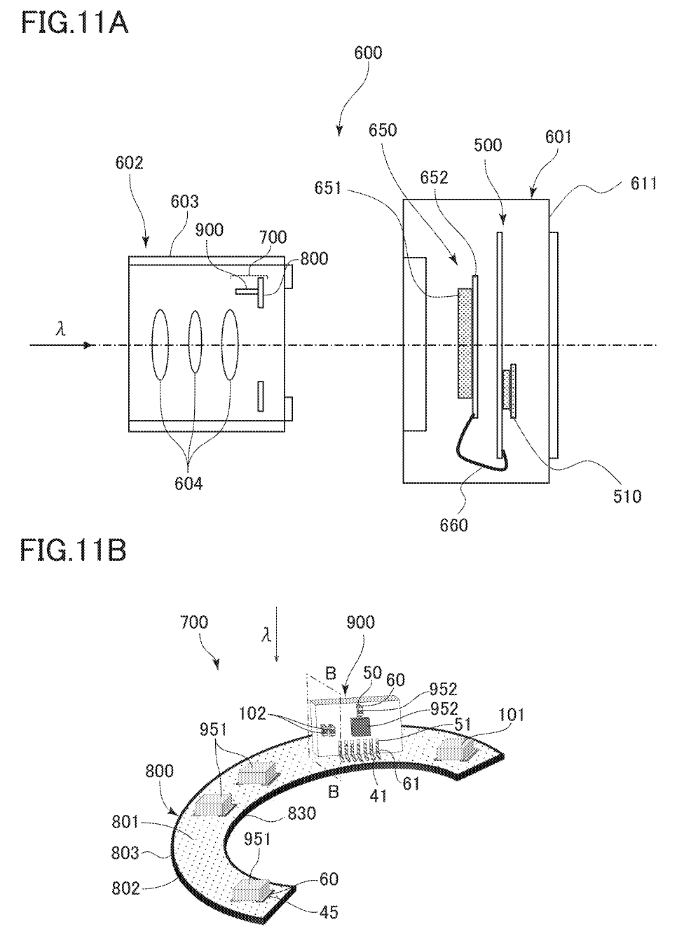

FIG. 11A is an explanatory diagram of a digital camera 600 serving as an example of a system according to the fourth embodiment. The digital camera 600 is a digital camera of a lens-replacing type in the present example, and includes a camera body 601 serving as an example of an electric device. A lens unit 602 including a lens is attachable to and detachable from the camera body 601. In the example of FIG. 11A, the lens unit 602 is detached from the camera body 601. The lens unit 602 is an example of an electric device. To be noted, the digital camera 600 is not limited to a digital camera of a lens-replacing type, and may be a digital camera of a lens-integrated type in which the camera body 601 and the lens unit 602 are integrated.

The lens unit 602 includes a casing 603, an electric module 700 disposed on the inside of the casing 603, and a lens group 604 constituted by a plurality of lenses disposed inside the casing 603. The lens group 604 is disposed at the center of the casing 603 where a light incident axis λ is located, and the electric module 700 is disposed at a position close to the inner peripheral surface of the casing 603 so as not to block the incident light.

FIG. 11B is a perspective view of the electric module 700 according to the fourth embodiment. The electric module 700 includes a wiring board 800, a wiring board 900 bonded to the wiring board 800, a plurality of electronic components 951, and a plurality of electronic components 952. The wiring board 800 is provided to be orthogonal to the light incident axis λ. The wiring board 900 is provided to be parallel to the light incident axis λ. The wiring board 800 is an example of a first electric board, and is a rigid board. The wiring board 900 is an example of a second electric board, and is a rigid board.

The wiring board 800 is, for example, a board of an annular shape or a partial annular shape. Here, the “partial annular shape” is a shape obtained by cutting out part of a ring. In the example of FIG. 11B, the wiring board 800 is a board of a partial annular shape. The wiring board 900 is, for example, a board of a rectangular shape. The wiring board 900 is orthogonally bonded to the wiring board 800. The plurality of electronic components 951 are mounted on the wiring board 800, and the plurality of electronic components 952 are mounted on the wiring board 900. At least one of the plurality of electronic components 951 and the plurality of electronic components 952 incorporates a control circuit for auto-focusing, or a power source circuit for driving.

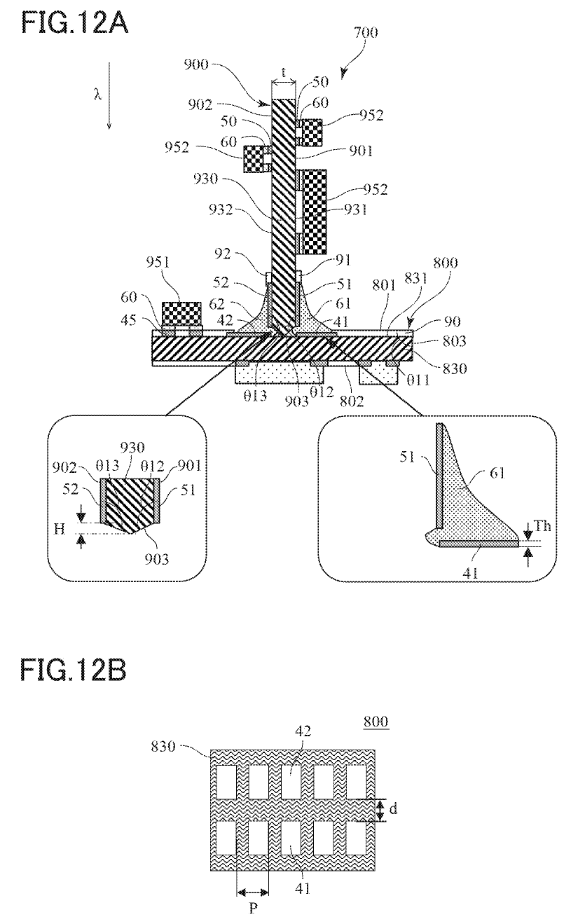

FIG. 12A is a section view of the electric module 700 according to the fourth embodiment. FIG. 12A illustrates a cross-section of the electric module 700 taken along a plane B-B illustrated in FIG. 11B. FIG. 12B is a plan view of part of the wiring board 800 according to the fourth embodiment. The plane B-B is a virtual plane orthogonal to a main surface 901 of the wiring board 900 that will be described later.

The wiring board 800 has a main surface 801 serving as an example of a first main surface, a main surface 802 serving as an example of a second main surface, and an end surface 803 serving as an example of a first end surface. The main surface 802 is a main surface on the opposite side to the main surface 801. The main surface 801 and the main surface 802 are each a mounting surface. The end surface 803 is an outer peripheral surface of the wiring board 800 disposed between the main surfaces 801 and 802 and connected to the main surfaces 801 and 802. The direction of the incident axis λ is a direction orthogonal to the main surface 801.

The wiring board 900 has a main surface 901 serving as an example of a third main surface, a main surface 902 serving as an example of a fourth main surface, and an end surface 903 serving as an example of a second end surface. The main surface 902 is a main surface on the opposite side to the main surface 901. The main surface 901 and the main surface 902 are each a mounting surface. The end surface 903 is an outer peripheral surface of the wiring board 900 disposed between the main surfaces 901 and 902 and connected to the main surfaces 901 and 902.

The main surface 801 of the wiring board 800 and the end surface 903 of the wiring board 900 oppose each other in the direction of the incident axis λ. In the fourth embodiment, the main surface 801 of the wiring board 800 and the end surface 903 of the wiring board 900 are in contact with each other.

The main surface 801 of the wiring board 800 and the main surface 901 of the wiring board 900 are bonded to each other via a plurality of bonding members 61. The main surface 801 of the wiring board 800 and the main surface 902 of the wiring board 900 are bonded to each other via a plurality of bonding members 62.

Each of the plurality of electronic components 951 is bonded to the main surface 801 or 802 of the wiring board 800 via a plurality of bonding members 60. Each of the plurality of electronic components 952 is bonded to the main surface 901 or 902 of the wiring board 900 via a plurality of bonding members 60.

The plurality of bonding members 61 are each an example of a first bonding member. The plurality of bonding members 62 are each an example of a second bonding member. The plurality of bonding members 60 are each formed from a conductive member such as solder. The plurality of bonding members 61 are each formed from a conductive member such as solder. The plurality of bonding members 62 are each formed from a conductive member such as solder.

The wiring board 800 includes an insulating substrate 830, a plurality of pads 45, 41, and 42 disposed on a main surface 831 of the insulating substrate 830, and a solder resist film 90 disposed around the plurality of pads 45, 41, and 42 and on the main surface 831 of the insulating substrate 830.

The plurality of pads 45, 41, and 42 are each a terminal formed from a metal material that is a conductive material, such as copper or gold. The material of the insulating substrate 830 is, for example, glass epoxy. The solder resist film 90 is a film formed from a solder resist material.

The main surface 801 of the wiring board 800 includes the surface of the solder resist film 90 and the surface of the plurality of pads 45, 41, and 42 exposed through the solder resist film 90. To be noted, the main surface 801 may include a portion of the main surface 831 of the insulating substrate 830 exposed through the solder resist film 90.

The plurality of electronic components 951 are bonded to the plurality of pads 45 via the plurality of bonding members 60.

The wiring board 900 includes an insulating substrate 930. The insulating substrate 930 has a main surface 931 and a main surface 932 on the opposite side to the main surface 931. The material of the insulating substrate 930 is, for example, glass epoxy.

In addition, the wiring board 900 includes a plurality of pads 50 and 51 disposed on the main surface 931 of the insulating substrate 930 and a plurality of pads 50 and 52 disposed on the main surface 932 of the insulating substrate 930. The plurality of pads 51 and the plurality of pads 52 are disposed adjacent to the end surface 903. The plurality of pads 50, 51, and 52 are each a terminal formed from a metal material that is a conductive material, such as copper or gold.

In addition, the wiring board 900 includes a solder resist film 91 disposed on the main surface 931 of the insulating substrate 930 and around the plurality of pads 50 and 51 on the main surface 931, and a solder resist film 92 disposed on the main surface 932 of the insulating substrate 930 and around the plurality of pads 50 and 52 on the main surface 932. The solder resist films 91 and 92 are each a film formed from a solder resist material.

The main surface 901 of the wiring board 900 includes the surface of the solder resist film 91 and the surface of the plurality of pads 50 and 51 on the main surface 931 exposed through the solder resist film 91. To be noted, the main surface 901 may include a portion of the main surface 931 of the insulating substrate 930 exposed through the solder resist film 91.

The main surface 902 of the wiring board 900 includes the surface of the solder resist film 92 and the surface of the plurality of pads 50 and 52 on the main surface 932 exposed through the solder resist film 92. To be noted, the main surface 902 may include a portion of the main surface 932 of the insulating substrate 930 exposed through the solder resist film 92.

The plurality of electronic components 952 are bonded to the plurality of pads 50 via the plurality of bonding members 60.

The plurality of pads 41 and the plurality of pads 51 are bonded to each other via the plurality of bonding members 61. The bonding members 61 are in contact with the pads 41 and 51. In addition, the plurality of pads 42 and the plurality of pads 52 are bonded to each other via the plurality of bonding members 62. The bonding members 62 are in contact with the pads 42 and 52.

As described above, the main surface 801 of the wiring board 800 and the main surface 901 of the wiring board 900 are bonded together via the plurality of bonding members 61, and are thus electrically and mechanically interconnected. The plurality of bonding members 61 are each used for power supply or signal transmission.

In addition, the main surface 801 of the wiring board 800 and the main surface 902 of the wiring board 900 are bonded together via the plurality of bonding members 62, and are thus electrically and mechanically interconnected. The plurality of bonding members 62 are each used for power supply or signal transmission.

In the fourth embodiment, at least an angle θ12 among an angle θ11 formed between the main surface 801 and the end surface 803 on the inner side of the wiring board 800 and an angle θ12 formed between the main surface 901 and the end surface 903 on the inner side of the wiring board 900 are each an obtuse angle of 120° or less. The angle θ11 is an example of a first angle, and the angle θ12 is an example of a second angle. In the example of FIG. 12A, the angle θ11 is a right angle, and the angle θ12 is an obtuse angle.

As described above, according to the fourth embodiment, as a result of at least the angle θ12 of the angle θ11 and the angle θ12 being 120° or less, the end surface 903 of the wiring board 900 has a tapered shape, and concentration of the stress on the bonding members 61 can be suppressed. This is because the rigidity of the tapered part of the wiring board 900 is relatively lower. As a result of this, the influence on the wiring board 900 from the impact when the electric module 700, that is, the lens unit 602 is dropped, or from temperature change in the heat cycle or the like caused by the temperature change in the environment or the start or stop of the operation of the digital camera 600 is reduced, and thus the stress acting on the bonding members 61 is reduced. Therefore, the reliability of bonding at the bonding members 61 is improved.

In addition, at least the angle θ12 of the angle θ11 and the angle θ12 may be an obtuse angle larger than 120°, but can be an obtuse angle of 120° or less, an obtuse angle of 105° or less, or an obtuse angle of 100°or less. As a result of this, in the wiring board 900, a wide region where mounted components such as the electronic components 952 can be mounted can be secured.

In addition, at least the angle θ12 of the angle θ11 and the angle θ12 can be, for example, an obtuse angle of 92° or more, and can be an obtuse angle of 95° or more. As a result of this, the reliability of bonding at the bonding members 61 is further improved.

In addition, in the fourth embodiment, an angle θ13 formed between the main surface 902 and the end surface 903 on the inner side of the wiring board 900 is an obtuse angle of 120° or less. The angle θ13 is an example of a seventh angle.

As described above, according to the fourth embodiment, as a result of the angle θ13 being 120° or less, concentration of the stress on the bonding members 62 can be suppressed. This is because the rigidity of the tapered part of the wiring board 900 is relatively lower. As a result of this, the influence on the wiring board 900 from the impact when the electric module 700, that is, the lens unit 602 is dropped, or from temperature change in the heat cycle or the like caused by the temperature change in the environment or the start or stop of the operation of the digital camera 600 is reduced, and thus the stress acting on the bonding members 62 is reduced. Therefore, the reliability of bonding at the bonding members 62 is improved.

In addition, the angle θ13 can be an obtuse angle of 105° or less or an obtuse angle of 100°or less. As a result of this, in the wiring board 900, a wide region where mounted components such as the electronic components 952 can be mounted can be secured.

In addition, at least the angle θ13 can be, for example, an obtuse angle of 92° or more, and can be an obtuse angle of 95° or more. As a result of this, the reliability of bonding at the bonding members 62 is further improved.

In some embodiments, the thickness of at least one of the wiring boards 800 and 900 is 0.1 mm or more and 10 mm or less. In more particular embodiments, the thickness of at least one of the wiring boards 800 and 900 is 5 mm or less. In even more particular embodiments, the thickness of at least one of the wiring boards 800 and 900 is 0.4 mm or more and 2 mm or less.

To be noted, although a case where the wiring boards 800 and 900 are each a rigid board has been described in the fourth embodiment, the configuration is not limited to this. For example, at least one of the wiring boards 800 and 900 may be a flexible board.

In addition, although a case where the first electric board is the wiring board 800 and the second electric board is the wiring board 900 has been described in the fourth embodiment, the configuration is not limited to this. For example, at least one of the first electric board and the second electric board may be a semiconductor board (single crystal, polycrystal, simple, or compound), a glass board, or a metal board. In addition, for example, at least one of the first electric board and the second electric board may be a board formed by bonding layers of different kinds such as a multilayer board (for example, a board in which an insulating layer is provided on a semiconductor layer or a board in which semiconductor layers of different kinds are laminated).

In the fourth embodiment, the end surface 903 of the wiring board 900 on the side where the pads 51 and 52 are formed has a convex shape protruding in the + direction of the incident axis λ with respect to the pads 51 and 52. That is, the end surface 903 of the wiring board 900 has a convex shape protruding toward the main surface 801 side of the wiring board 800. In the fourth embodiment, the end surface 903 of the wiring board 900 has a V shape in the cross-section taken along the plane B-B, and is thus easily comes into contact with the main surface 801 of the wiring board 800. In the fourth embodiment, the end surface 903 of the wiring board 900 is in contact with the insulating substrate 830. The end surface 903 of the wiring board 900 is not in contact with the pads 41 and 42. As a result of the end surface 903 of the wiring board 900 coming into contact with the main surface 801 of the wiring board 800, the posture of the wiring board 800 becomes stable, concentration of the stress on the bonding members 61 and 62 is suppressed, and the reliability of the bonding at the bonding members 61 and 62 is further improved.

The height H from the ends of the pads 51 and 52 to the distal end of the end surface 903 having a convex shape can be equal to or larger than the thickness Th of the pads 41 and 42 of the wiring board 800. The height H is a protrusion amount of the end surface 903 in the direction of the incident axis λ.

As a result of the height H being equal to or larger than the thickness Th, the back fillet is formed right under the bonding members 61 and 62 of the wiring board 900, and thus the reliability of bonding at the bonding members 61 and 62 is further improved. The height H can be equal to or less than the pitch P of the pads 41 (42). As a result of this, the fillet of the bonding members 61 and 62 is large, and thus the reliability of the bonding at the bonding members 61 and 62 is further improved.

In a state in which the distal end of the convex shape of the wiring board 900 is opposed to the main surface 801 of the wiring board 800, the pads 41 and 42 of the wiring board 800 are connected to the pads 51 and 52 of the wiring board 900 respectively via the bonding members 61 and 62. Since the height H is equal to or larger than the thickness Th, a space is formed between the pads 41 and 42 and the pads 51 and 52. The bonding members 61 and 62 are provided to fill this space, and are in contact with the end surface 903 of the wiring board 900. When an external force is applied to the wiring board 900, stress is generated at the bonding members 61 and 62. In the fourth embodiment, the end surface 903 of the wiring board 900 has a tapered shape, and the bonding members 61 and 62 are in contact with the end surface 903 in a shape following the tapered shape. Therefore, the stress is distributed, and the reliability of the bonding at the bonding members 61 and 62 is improved.

The end surface 903 having the convex shape of the wiring board 900 is disposed between the pads 41 and the pads 42 of the wiring board 800. The solder resist film 90 may or may not be disposed between the pads 41 and the pads 42 of the wiring board 800 on the main surface 831 of the insulating substrate 830 of the wiring board 800. In the fourth embodiment, the solder resist film 90 is not disposed between the pads 41 and the pads 42 of the wiring board 800 on the main surface 831 of the insulating substrate 830 of the wiring board 800, and the flat surface portion of the main surface 801 of the wiring board 800 between the pads 41 and the pads 42 is recessed in the + direction of the incident axis λ by an amount corresponding to the thickness Th of the pads 41 and 42. Since the convex shape of the wiring board 900 is disposed in the recessed portion of the main surface 801 of the wiring board 800, the wiring board 900 is positioned with respect to the wiring board 800 at the time of bonding, and thus displacement of the wiring board 900 is suppressed.

In the case where the thickness t of the wiring board 900 is smaller than the distance d between the pads 41 and the pads 42 of the wiring board 800, the position of the wiring board 900 can be adjusted such that the wiring board 900 does not overlap with either of the pads 41 and the pads 42 when bonding the wiring board 900 to the wiring board 800, and thus the wiring board 900 can be positioned with respect to the wiring board 800 more precisely.

For the electric module 700, for example, as a result of the electronic components 952 including a driver circuit being mounted on the wiring board 900, the number of parts mounted on the wiring board 800 can be reduced, and the area of the wiring board 800 can be reduced.

As a method for reducing the area, the space for the lens group 604 can be widened by increasing the inner diameter without changing the external shape of the wiring board 800. By increasing the size of the external shape of lenses included in the lens group 604, miniaturization by reducing the length of the lens unit 602 can be made possible, and the field of view as the optical function can be made wider.

To be noted, although a case where a cross-section of the end surface 903 of the wiring board 900 taken along the plane B-B has a V shape has been described in the fourth embodiment, the configuration is not limited to this. For example, the cross-section of the end surface 903 of the wiring board 900 along the plane B-B may have a trapezoidal shape.

### Fifth Embodiment

An electric module according to a fifth embodiment will be described. In the description below, it is assumed that elements denoted by the same reference signs as in the embodiments described above have substantially the same configurations and functions as those described in the embodiments described above unless described otherwise, and part different from the embodiments described above will be mainly described.

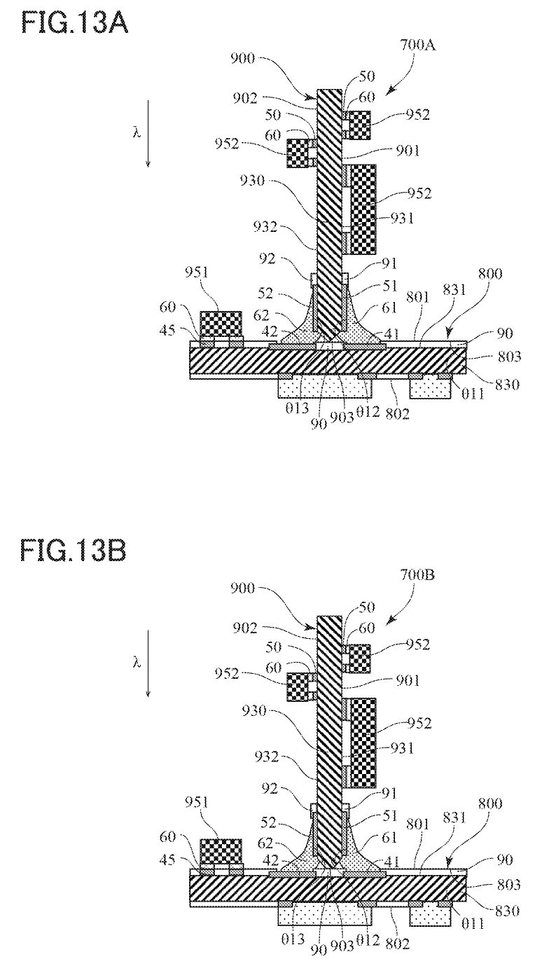

FIG. 13A is a section view of an electric module 700A according to the fifth embodiment. The lens unit according to the fifth embodiment has a configuration in which the electric module 700 in the lens unit 602 illustrated in FIG. 11A is replaced by the electric module 700A illustrated in FIG. 13A. FIG. 13A illustrates a cross-section of the electric module 700A taken along a virtual plane orthogonal to the main surface 901 of the wiring board 900.

Although a case where the end surface 903 of the wiring board 900 comes into contact with the insulating substrate 830 of the wiring board 800 has been described in the fourth embodiment described above, the configuration is not limited to this. In the fifth embodiment, as illustrated in FIG. 13A, the solder resist film 90 covering the main surface 831 of the insulating substrate 830 is disposed also between the pads 41 and 42, and the end surface 903 of the wiring board 900 is in contact with the solder resist film 90 of the wiring board 800. The end surface 903 of the wiring board 900 is not in contact with the pads 41 and 42. In the fourth embodiment, the end surface 903 of the wiring board 900 has a convex shape, and the cross-section of the end surface 903 along the virtual plane has a V shape.

As described above, in the fifth embodiment, the pads 41 and 42 are surrounded by the solder resist film 90, and the solder resist film 90 is also disposed right under the wiring board 900. Therefore, in the case where an external force is applied to the wiring board 900, peeling of the pads 41 and 42 of the wiring board 800 from the insulating substrate 830 is suppressed, and thus the reliability of the bonding is secured for a long period of time.

### Modification Example of Fifth Embodiment

FIG. 13B is a section view of an electric module 700B according to a modification example of the fifth embodiment. The lens unit according to the modification example of the fifth embodiment has a configuration in which the electric module 700 in the lens unit 602 illustrated in FIG. 11A is replaced by the electric module 700B illustrated in FIG. 13B. FIG. 13B illustrates a cross-section of the electric module 700B taken along a virtual plane orthogonal to the main surface 901 of the wiring board 900.

To be noted, although a case where a cross-section of the end surface 903 of the wiring board 900 along the virtual plane has a V shape has been described in the fifth embodiment described above, the configuration is not limited to this. In the modification example of the fifth embodiment, the cross-section of the end surface 903 of the wiring board 900 along the virtual plane has a trapezoidal shape. The virtual plane is a plane orthogonal to the main surface 901 of the wiring board 900. A similar effect to the fifth embodiment can be obtained even if the end surface 903 of the wiring board 900 has a trapezoidal shape.

### Sixth Embodiment

An electric module according to a sixth embodiment will be described. In the description below, it is assumed that elements denoted by the same reference signs as in the embodiments described above have substantially the same configurations and functions as those described in the embodiments described above unless described otherwise, and part different from the embodiments described above will be mainly described.

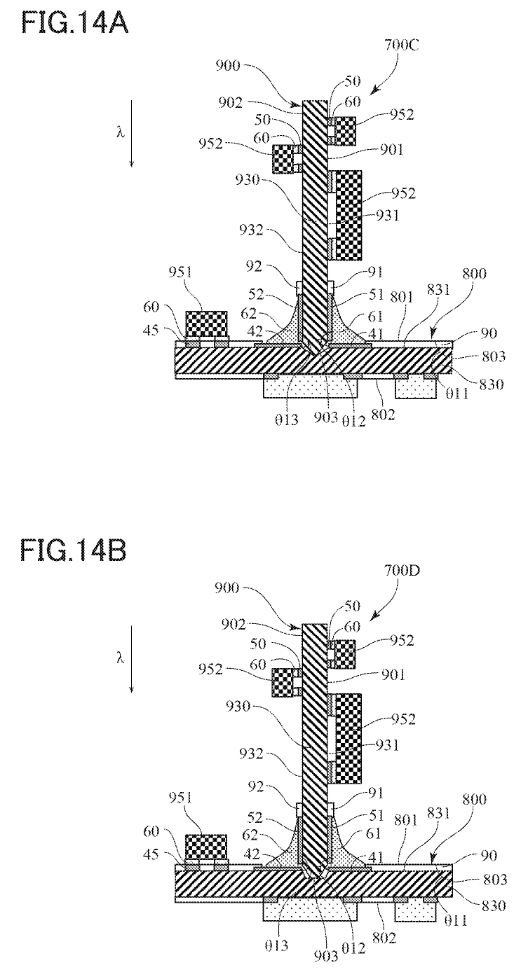

FIG. 14A is a section view of an electric module 700C according to the sixth embodiment. The lens unit according to the sixth embodiment has a configuration in which the electric module 700 in the lens unit 602 illustrated in FIG. 11A is replaced by an electric module 700C illustrated in FIG. 14A. FIG. 14A illustrates a cross-section of the electric module 700C taken along a virtual plane orthogonal to the main surface 901 of the wiring board 900.

Although a case where the end surface 903 of the wiring board 900 comes into contact with a flat surface portion of the main surface 831 of the insulating substrate 830 of the wiring board 800 between the pads 41 and the pads 42 has been described in the fourth embodiment described above, the configuration is not limited to this.

In the sixth embodiment, the portion of the main surface 831 of the insulating substrate 830 that the end surface 903 of the wiring board 900 comes into contact with is not a flat surface but a groove recessed in the + direction of the incident axis λ with respect to the flat surface. That is, the portion of the main surface 831 of the insulating substrate 830 of the wiring board 800 between the pads 41 and the pads 42 is recessed. The end surface 903 of the wiring board 900 is in contact with the bottom of the recess portion (groove) between the pads 41 and the pads 42. The end surface 903 of the wiring board 900 is not in contact with the pads 41 and 42. In the sixth embodiment, the end surface 903 of the wiring board 900 has a convex shape, and the cross-section of the end surface 903 taken along the virtual plane has a V shape. Further, the cross-section of the recess portion (groove) of the main surface 831 of the insulating substrate 830 taken along the virtual plane has a V shape. In this manner, the wiring board 900 is more likely to stand on its own when bonding the wiring board 900 to the wiring board 800, and thus the wiring board 900 can be stably bonded to the wiring board 800.

### Modification Example of Sixth Embodiment

FIG. 14B is a section view of an electric module 700D according to the sixth embodiment. The lens unit according to the sixth embodiment has a configuration in which the electric module 700 in the lens unit 602 illustrated in FIG. 11A is replaced by an electric module 700D illustrated in FIG. 14B. FIG. 14B illustrates a cross-section of the electric module 700D taken along a virtual plane orthogonal to the main surface 901 of the wiring board 900.

Although a case where the cross-section of the end surface 903 of the wiring board 900 taken along the virtual plane has a V shape and the portion of the main surface 831 of the insulating substrate 830 of the wiring board 800 between the pads 41 and the pads 42 is a recess portion (groove) having a V-shaped cross-section has been described in the sixth embodiment described above, the configuration is not limited to this. In the modification example of the sixth embodiment, the cross-section of the end surface 903 of the wiring board 900 taken along the virtual plane has a trapezoidal shape. The virtual plane is a plane orthogonal to the main surface 901 of the wiring board 900. Further, the cross-section of the portion of the main surface 831 of the insulating substrate 830 of the wiring board 800 between the pads 41 and the pads 42 is a recess portion (groove) having a trapezoidal shape. As described above, a similar effect to the sixth embodiment can be also obtained in the case where the end surface 903 of the wiring board 900 has a trapezoidal shape and the portion of the main surface 831 that the end surface 903 comes into contact with has a trapezoidal shape.

### Seventh Embodiment

An electric module according to a seventh embodiment will be described. In the description below, it is assumed that elements denoted by the same reference signs as in the embodiments described above have substantially the same configurations and functions as those described in the embodiments described above unless described otherwise, and part different from the embodiments described above will be mainly described.

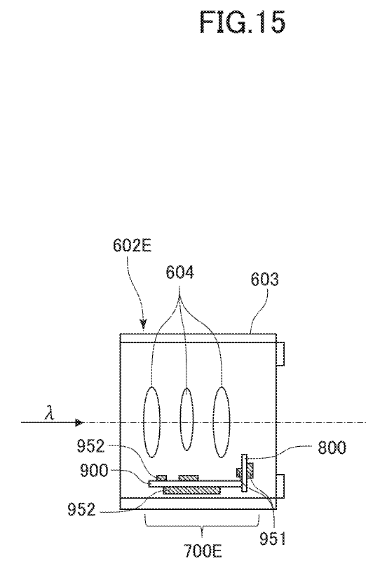

FIG. 15 is an explanatory diagram of a lens unit 602E according to the seventh embodiment. The lens unit 602E according to the seventh embodiment has a configuration in which the electric module 700 in the lens unit 602 illustrated in FIG. 11A is replaced by an electric module 700E illustrated in FIG. 15.

The lens unit 602E includes a casing 603, an electric module 700E disposed on the inside of the casing 603, and a lens group 604 constituted by a plurality of lenses disposed inside the casing 603. The lens group 604 is disposed at the center of the casing 603 where a light incident axis λ is located, and the electric module 700E is disposed at a position close to the inner peripheral surface of the casing 603 so as not to block the incident light.

The electric module 700E includes a wiring board 800, a wiring board 900 bonded to the wiring board 800, a plurality of electronic components 951 mounted on the wiring board 800, and a plurality of electronic components 952 mounted on the wiring board 900. The wiring board 800 is provided to be orthogonal to the light incident axis λ. The wiring board 900 is provided to be parallel to the light incident axis λ.

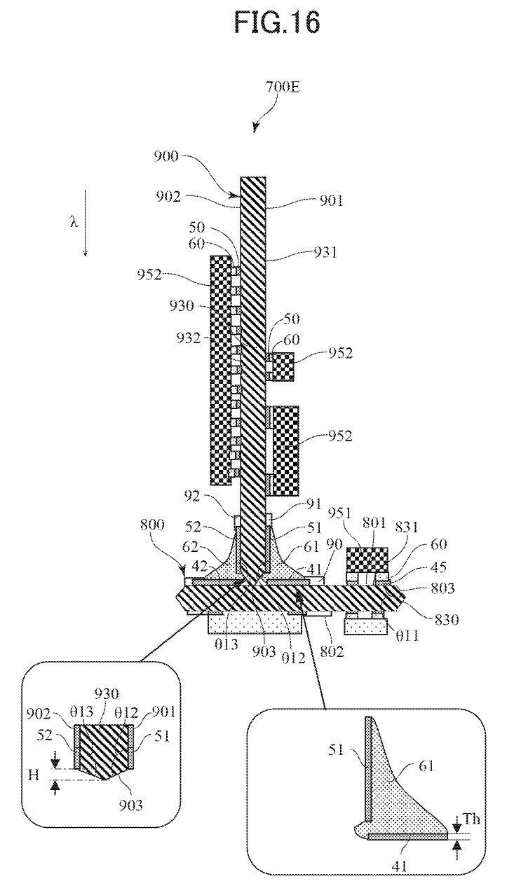

FIG. 16 is a section view of the electric module 700E according to the seventh embodiment. FIG. 16 illustrates a cross-section of the electric module 700E taken along a virtual plane orthogonal to the main surface 901 of the wiring board 900.

The main surface 801 of the wiring board 800 and the end surface 903 of the wiring board 900 oppose each other in the direction of the incident axis λ. In the seventh embodiment, the main surface 801 of the wiring board 800 and the end surface 903 of the wiring board 900 are in contact with each other.

The main surface 801 of the wiring board 800 and the main surface 901 of the wiring board 900 are bonded to each other via a plurality of bonding members 61. The main surface 801 of the wiring board 800 and the main surface 902 of the wiring board 900 are bonded to each other via a plurality of bonding members 62.

In the seventh embodiment, at least an angle θ12 among an angle θ11 formed between the main surface 801 and the end surface 803 on the inner side of the wiring board 800 and an angle θ12 formed between the main surface 901 and the end surface 903 on the inner side of the wiring board 900 is an obtuse angle of 120° or less. The angle θ11 is an example of a first angle, and the angle θ12 is an example of a second angle. In the example of FIG. 16, the angle θ11 and the angle θ12 are each an obtuse angle of 120° or less. That is, in the seventh embodiment, the end surface 803 of the wiring board 800 also has a convex shape.

As described above, according to the seventh embodiment, as a result of the angle θ11 being 120° or less, warpage of the wiring board 800 is suppressed, and concentration of stress at the bonding members 61 and 62 can be suppressed. As a result of this, the influence on the wiring board 900 from the impact when the electric module 700E, that is, the lens unit 602E is dropped, or from temperature change in the heat cycle or the like caused by the temperature change in the environment or the start or stop of the operation of the digital camera 600 is reduced, and thus the stress acting on the bonding members 61 and 62 is reduced. Therefore, the reliability of bonding at the bonding members 61 and 62 is improved.

In addition, the angle θ11 can be an obtuse angle of 105° or less, or an obtuse angle of 100°or less. As a result of this, in the wiring board 800, a wide region where mounted components such as the electronic components 951 can be mounted can be secured.

In addition, the angle θ11 can be, for example, an obtuse angle of 92° or more, and can be an obtuse angle of 95° or more. As a result of this, the reliability of bonding at the bonding members 61 and 62 is further improved.

The height H from the ends of the pads 51 and 52 to the distal end of the end surface 903 having a convex shape can be equal to or larger than the thickness Th of the pads 41 and 42 of the wiring board 800. The height H is a protrusion amount of the end surface 903 in the direction of the incident axis λ.

As a result of the height H being equal to or larger than the thickness Th, the back fillet is formed right under the bonding members 61 and 62 of the wiring board 900, and thus the reliability of bonding at the bonding members 61 and 62 is further improved. The height H can be equal to or less than the pitch P of the pads 41 (42). As a result of this, the fillet of the bonding members 61 and 62 is large, and thus the reliability of the bonding at the bonding members 61 and 62 is further improved.

Similarly to the fourth embodiment, an end portion of the wiring board 900 on the side on which the pads 51 and 52 are formed has a convex shape. In a state in which the distal end of the convex shape of the wiring board 900 is opposed to the main surface 801 of the wiring board 800, the pads 41 and 42 of the wiring board 800 are connected to the pads 51 and 52 of the wiring board 900 respectively via the bonding members 61 and 62. Since the height H is equal to or larger than the thickness Th, a space is formed between the pads 41 and 42 and the pads 51 and 52. The bonding members 61 and 62 are provided to fill this space, and are in contact with the end surface 903 of the wiring board 900. When an external force is applied to the wiring board 900, stress is generated at the bonding members 61 and 62. In the seventh embodiment, the end surface 903 of the wiring board 900 has a tapered shape, and the bonding members 61 and 62 are in contact with the end surface 903 in a shape following the tapered shape. Therefore, the stress is distributed, and the reliability of the bonding at the bonding members 61 and 62 is improved.

In addition, since an end portion of the wiring board 800, especially the angle θ11 formed between the main surface 801 and the end surface 803 is an obtuse angle as described above, the external force applied to the end portion of the wiring board 800 is distributed, the stress on the bonding members 61 and 62 is distributed, and the reliability of the bonding is improved.

For the electric module 700E, for example, as a result of the electronic components 952 including a driver circuit being mounted on the wiring board 900, the number of parts mounted on the wiring board 800 can be reduced, and the area of the wiring board 800 can be reduced. The space for the lens group 604 can be increased by reducing the area of the wiring board 800. By increasing the size of the external shape of lenses, miniaturization by reducing the length of the lens unit 602E can be made possible, and the field of view as the optical function can be made wider.

### Example 1

Example 1 corresponding to the first embodiment will be described with reference to FIGS. 1 to 5. The size of each part of the processing module 500 is as follows. Regarding the external shape of the wiring board 220, the length of each of the sides 1 and 2 was 16.40 mm, and the length of each of the sides 3 and 4 was 15.20 mm. In addition, the thickness of the wiring board 220 including the solder resist films 251 and 252 was about 0.50 mm, and the thickness of the solder resist film 251 and the thickness of the solder resist film 252 were each about 0.015 mm.

The bonding members 610 were arranged in a staggered pattern at a pitch of 0.40 mm. In addition, the bonding members 620 were arranged in a staggered pattern at a pitch of 0.60 mm so as to surround the outer periphery of the semiconductor element 210.

The height from the main surface 101 of the wiring board 100 to the main surface 301 of the wiring board 300 in a state in which the bonding members 610 and 620 were formed was about 0.90 mm.

Regarding the sides 1 to 4 of the wiring board 220 and the sides 10 to 40 of the wiring board 300, the angles θ2 to θ5 of the tapered shapes were 96°, and the end surfaces 203 and 303 of the wiring board 220 and 300 each had a convex V shape whose center in the thickness direction protruded toward the outer peripheral side.

Resin was applied on the sides 1 to 4 of the wiring board 220 and the sides 10 to 40 of the wiring board 300. The resin was applied by moving a nozzle attached to an unillustrated dispenser while ejecting the resin from the nozzle.

The processing module 500 was heated in an unillustrated oven to cure the resin, and thus the resin reinforcement member 410 was formed. Regarding the curing conditions in the oven, the temperature in the oven was set to 125°C, and the heating time was set to 30 min. The height 421 of the resin reinforcement member 410 was equal to or less than that of the main surface 302 of the wiring board 300, the end surface 303 of the sides 10 to 40 of the wiring board 300 was covered by the resin, and the height 421 was about 1.3 mm from the main surface 101 of the wiring board 100. In this manner, the processing module 500 was manufactured.

### Example 2

Example 2 corresponding to the second embodiment will be described with reference to FIGS. 6 to 8. In the three-dimensional mounting structure of Example 1 before being subjected to resin application, two plates 450 and five chip components of a 0402 size were mounted as a plurality of electronic components 460. The two plates 450 each had a size of 7.5 mm × 15.20 mm and a thickness of 0.5 mm. The height from the main surface 302 of the wiring board 300 to the main surface 401 of the plate 450 was about 0.90 mm. The angle θ6 of the tapered shape of the end surface 403 of the plate 450 was 97°, and a portion of the tapered shape farther from the main surface 302 of the wiring board 300 was wider. The thickness of the solder resist film, the pitch of the bonding members, the resin application method, and the like were substantially the same as in Example 1. The height of the resin reinforcement member 410 was equal to or less than that of the main surface 402 of the plate 450, and was about 1.8 mm from the main surface 101 of the wiring board 100. In this manner, the processing module 500A was manufactured.

### Example 3

Example 3 corresponding to the fourth embodiment will be described with reference to FIGS. 11A to 12B. The wiring board 800 of the third embodiment was a six-layer wiring board in which FR-4 insulating layers and copper wiring layers were laminated. The size of the wiring board 800 was as follows: outer diameter of 54 mm; inner diameter of 45 mm; and thickness of 1.0 mm. The pads 41 and 42 on the surface layer of the wiring board 800 each had a thickness of 0.015 mm, a width of 0.125 mm, and a length of 1.0 mm. In addition, the pitch of the plurality of pads 41 and the pitch of the plurality of pads 42 were each 0.25 mm, and the pads 41 and the pads 42 were each arranged in a line. The number of the plurality of pads 41 was set to 30, and the number of the plurality of pads 42 was set to 30, which made a total of 60.

In addition, the wiring board 900 was a six-layer wiring board in which FR-4 insulating layers and copper wiring layers were laminated. The size of the wiring board 900 was as follows: width of 13 mm; height of 7 mm; and thickness of 0.8 mm. The pads 51 and 52 were formed on the front side and the back side of the wiring board 900. The pads 51 and 52 formed from copper each had a thickness of 0.015 mm, a width of 0.125 mm, and a length of 1.0 mm. In addition, the pitch of the plurality of pads 51 and the pitch of the plurality of pads 52 were each 0.25 mm. The number of the plurality of pads 51 was set to 30, and the number of the plurality of pads 52 was set to 30, which made a total of 60.

The end surface 903 of the wiring board 900 on the side on which the pads 51 and 52 were formed had a convex shape. As the convex shape, a tapered shape was formed from the pads 51 and 52 toward the distal end of the wiring board 900. The angles θ12 and θ13 were each about 95°, and the height H from an end of the pads 51 to 52 to the distal end of the convex shape was 0.15 mm, which was equal to or larger than the thickness Th of the pads 41 and 42 of the wiring board 800.

Since the height H was equal to or larger than the thickness Th, a space was formed between the pads 41 and 42 and the pads 51 and 52. The bonding members 61 and 62 were provided to fill this space, and were in contact with the end surface 903 of the wiring board 900. The metal composition of the solder of the bonding members 61 and 62 was Sn-3.0Ag-0.5Cu.

When an external force is applied to the wiring board 900 in a state in which the wiring board 900 is connected to the wiring board 800, stress is generated in the bonding members 62 used for bonding. Since the bonding members 61 and 62 each have a shape following the tapered shape of the end portion of the wiring board 900, the stress is distributed, thus the bonding members 61 and 62 do not break even after a dropping impact test, and the reliability of bonding is secured.

### Example 4

Example 4 corresponding to the fifth embodiment and the modification example thereof will be described with reference to FIGS. 13A and 13B. In the fifth embodiment, the pads 41 and 42 of the wiring board 800 are surrounded by the solder resist film 90. The thickness of the solder resist film 90 was 0.02 mm. In a structure disposed orthogonally with respect to the wiring board 800, the solder resist film 90 was disposed also right under the wiring board 900. Therefore, in the case where an external force is applied to the wiring board 900, peeling of the pads 41 and 42 of the wiring board 800 from the insulating substrate 830 could be suppressed, and thus the reliability of the bonding could be secured for a long period of time.

### Example 5

Example 5 corresponding to the sixth embodiment and the modification example thereof will be described with reference to FIGS. 14A and 14B. The end surface 903 of the wiring board 900 on the side on which the pads 51 and 52 were formed had a convex shape. As the convex shape, a tapered shape was formed from the pads 51 and 52 toward the distal end of the wiring board 900. The angles θ12 and θ13 of the tapered shape were each about 95°, and the height from an end of the pads 51 to 52 to the distal end of the convex shape was 0.15 mm, which was equal to or larger than the thickness of the pads 41 and 42 of the wiring board.

In Example 5, the main surface 801 of the wiring board 800 opposing the wiring board 900, that is, the main surface 831 of the insulating substrate 830 had a recessed shape. The recessed shape was formed between the pads 41 and the pads 42 of the wiring board 800. The recess shape had a depth of 0.015 mm and a width of 0.8 mm.

As illustrated in FIG. 14A, the convex shape of the end surface 903 of the wiring board 900 was a V shape. By forming the main surface 801 of the wiring board 800, that is, the recess shape of the main surface 831 of the insulating substrate 830 in a V shape, the wiring board 900 was more likely to stand on its own when bonding to the wiring board 900 to the wiring board 800.

In addition, as illustrated in FIG. 14B, the convex shape of the end surface 903 of the wiring board 900 was a trapezoidal shape, and the main surface 801 of the wiring board 800, that is, the recess shape of the main surface 831 of the insulating substrate 830 was a trapezoidal shape. The angles θ12 and θ13 of the tapered shape were each about 95°, the height from an end of the pads 51 to 52 to the distal end of the convex shape was 0.15 mm, and the width of the end surface 903 was 0.3 mm. The main surface 801 of the wiring board 800 opposing the wiring board 900, that is, the main surface 831 of the insulating substrate 830 had a recess shape. The recess shape was formed between the pads 41 and the pads 42 of the wiring board 800. Regarding the size of the recess shape, the depth was 0.015 mm, the opening width on the upper side was 0.8 mm, and the width of the bottom surface was 0.3 mm. As a result of this shape, the wiring board 900 was more likely to stand on its own when bonding the wiring board 900 to the wiring board 800.

### Example 6

Example 6 corresponding to the seventh embodiment will be described with reference to FIG. 16. The end surface 803 of the wiring board 800 had a tapered shape. The wiring board 900 had a width of 25 mm, a length of 25 mm, and a thickness of 1.0 mm, and electronic components 952 each having a size of 10 mm × 10 mm was mounted on the wiring board 900. The pads 41, 42, 51, and 52 connected to the bonding members 61 and 62 were each formed from copper, and had a thickness of 0.015 mm, a width of 0.125 mm, and a length of 1.0 mm. In addition, the pitch of the pads 41, the pitch of the pads 42, the pitch of the pads 51, and the pitch of the pads 52 were each 0.25 mm, and the numbers thereof were each 30. The configuration was the same as that of Example 3 except for these.

When an external force is applied to the wiring board 900, stress is generated in the bonding members 61 and 62. Since the end surface 903 of the wiring board 900 has a tapered shape, the stress is distributed, thus the bonding members 61 and 62 do not break even after a dropping impact test, and the reliability of bonding is secured.

### Other Modification Examples

The present disclosure is not limited to the embodiments described above, and the embodiments can be modified in many ways within the technical concept of the present disclosure. For example, at least two of the plurality of embodiments and plurality of modification examples described above may be combined. In addition, the effects described in the embodiments are merely enumeration of the most preferable effects that can be obtained from the embodiments of the present disclosure, and the effects of the embodiments of the disclosure are not limited to those described in the embodiments.

In addition, the electric device to which the embodiments described above can be applied is not limited to an image pickup device such as a camera body or an optical device such as a lens unit. For example, the electric device may be an information device such as a smartphone or a personal computer, or a communication device such as a modem or a router. Alternatively, the electric device may be an office appliance such as a printer or a copier, a medical device such as an X-ray imaging device or an endoscope, an industrial device such as a robot or a semiconductor manufacturing apparatus, or a transport device such as a car, an airplane, or a ship. The board having an annular shape or a partial annular shape can be used for a robot arm.

The semiconductor element included in the semiconductor device mounted on the wiring board may be any of a storage element (memory), a processing element (processor), a detection element (sensor), a display element (display), a control element, a communication element, and the like. The storage element may be, for example, a dynamic random access memory (DRAM) or a flash memory. The processing element is, for example, a central processing unit (CPU), a graphics processing unit (GPU), a neural processing unit (NPU), a digital signal processor (DSP), or an image signal processor (ISP). The detection element is, for example, a CMOS image sensor, a single photon avalanche diode (SPAD) sensor, or a micro electro mechanical systems (MEMS) sensor. The display element is, for example, a liquid crystal display or an organic electroluminescent display. The control element is a control integrated circuit (IC), or a power source IC. The communication element is, for example, an IC for wireless communication or an interface IC.

The electric board is not limited to a wiring board, and the electric board itself may have an electric function other than a wiring function. For example, if a semiconductor substrate is used for the electric board, an electromotive force derived from photoelectric conversion may be imparted to the electric board similarly to a solar cell. In addition, the electric board may be a display panel or the like, and in this case, an active element such as a thin film transistor, matrix wiring, and the like may be disposed on an insulating substrate such as glass or plastics.

The disclosure of the present specification is not limited to what is explicitly described in the present specification, and includes all the matter that can be grasped from the present specification and drawings attached to the present specification. In addition, the disclosure of the present specification includes a subset of individual concepts described in the present specification. That is, if the present specification includes description of, for example, “A is B”, it can be said that the present specification discloses a concept of “A is not B” even if a description of “A is not B” is omitted. This is because description of “A is B” is made on the premise that a case of “A is not B” has been already considered.

As described above, according to the present disclosure, a technique advantageous for improving the reliability of bonding can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-217045, filed December 11, 2024, which is hereby incorporated by reference herein in its entirety.

What is claimed is:

1. An electric module comprising:
a first electric board; and
a second electric board,
wherein the first electric board has a first main surface, a second main surface provided on an opposite side to the first main surface, and a first end surface connected to the first main surface and the second main surface,
wherein the second electric board has a third main surface, a fourth main surface provided on an opposite side to the third main surface, and a second end surface connected to the third main surface and the fourth main surface,
wherein the first main surface of the first electric board and the third main surface of the second electric board are electrically interconnected by being bonded to each other via a first bonding member, and
wherein a first angle formed between the first main surface and the first end surface on an inner side of the first electric board and/or a second angle formed between the third main surface and the second end surface on an inner side of the second electric board are each an obtuse angle of 105° or less.

2. The electric module according to claim 1, wherein the first angle and/or the second angle are each an obtuse angle of 95° or more.

3. The electric module according to claim 1, wherein an angle formed between the second main surface and the first end surface on the inner side of the first electric board and/or an angle formed between the fourth main surface and the second end surface on the inner side of the second electric board are each an obtuse angle of 120° or less.

4. The electric module according to claim 1, wherein an angle formed between a portion of the first end surface connected to the first main surface and a portion of the first end surface connected to the second main surface on the inner side of the first electric board and/or an angle formed between a portion of the second end surface connected to the third main surface and a portion of the second end surface connected to the fourth main surface on the inner side of the second electric board are each an obtuse angle of 120° or more.

5. The electric module according to claim 1, wherein a thickness of at least one of the first electric board or the second electric board is 0.4 mm or more and 2 mm or less.

6. The electric module according to claim 1, further comprising:
a third electric board,
wherein the third electric board has a fifth main surface, a sixth main surface provided on an opposite side to the fifth main surface, and a third end surface connected to the fifth main surface and the sixth main surface,
wherein the fourth main surface of the second electric board and the fifth main surface of the third electric board are electrically interconnected by being bonded to each other via a second bonding member, and
wherein a third angle formed between the fourth main surface and the second end surface on an inner side of the second electric board and/or a fourth angle formed between the fifth main surface and the third end surface on an inner side of the third electric board are each an obtuse angle of 120° or less.

7. The electric module according to claim 6,
wherein the second electric board is a wiring member electrically interconnecting the first electric board and the third electric board and configured to maintain a gap between the first electric board and the third electric board, and
wherein an electronic component is disposed between the first electric board and the third electric board.

8. The electric module according to claim 6, further comprising:
a plate,
wherein the plate has a seventh main surface, an eighth main surface provided on an opposite side to the seventh main surface, and a fourth end surface connected to the seventh main surface and the eighth main surface,
wherein the sixth main surface of the third electric board and the seventh main surface of the plate are bonded by a third bonding member, and
wherein a fifth angle formed between the sixth main surface and the third end surface on the inner side of the third electric board and/or a sixth angle formed between the seventh main surface and the fourth end surface on an inner side of the plate are each an obtuse angle of 120° or less.

9. The electric module according to claim 1, wherein the first main surface of the first electric board and the third main surface of the second electric board are opposed to each other in a direction orthogonal to the first main surface.

10. The electric module according to claim 1, further comprising:
a resin reinforcement member,
wherein the resin reinforcement member is in contact with the first main surface of the first electric board and the second end surface of the second electric board.

11. An electric module comprising:
a first electric board; and
a second electric board,
wherein the first electric board has a first main surface, a second main surface provided on an opposite side to the first main surface, and a first end surface connected to the first main surface and the second main surface,
wherein the second electric board has a third main surface, a fourth main surface provided on an opposite side to the third main surface, and a second end surface connected to the third main surface and the fourth main surface,
wherein the first main surface of the first electric board and the third main surface of the second electric board are electrically interconnected by being bonded to each other via a first bonding member,
wherein the first main surface of the first electric board and the second end surface of the second electric board are opposed to each other in a direction orthogonal to the first main surface, and
wherein at least an angle formed between the third main surface and the second end surface on an inner side of the second electric board is an obtuse angle of 120° or less.

12. The electric module according to claim 11,
wherein the first main surface of the first electric board and the fourth main surface of the second electric board are electrically interconnected by being bonded to each other via a second bonding member, and
wherein an angle formed between the fourth main surface and the second end surface on the inner side of the second electric board is an obtuse angle.

13. The electric module according to claim 11, wherein the electric module satisfies at least one of the following:
(1) the second end surface is in contact with the first main surface;
(2) the second end surface is in contact with a recess portion of the first main surface;
(3) the second end surface has a convex shape protruding toward the first main surface; or
(4) the second end surface has a V shape or a trapezoidal shape.

14. The electric module according to claim 11,
wherein the first electric board includes an insulating substrate, and a pad that is disposed on the first main surface side with respect to the insulating substrate and that is in contact with the first bonding member, and
wherein the electric module satisfies at least one of the following:
(5) a protrusion amount of the second end surface in a direction orthogonal to the first main surface is equal to or larger than a thickness of the pad in the direction orthogonal to the first main surface;
(6) the second end surface is in contact with the insulating substrate; or
(7) part of the insulating substrate opposed to the second end surface is recessed.

15. The electric module according to claim 14, wherein the first electric board includes a solder resist film disposed on the first main surface side with respect to the insulating substrate.

16. The electric module according to claim 11,
wherein the first electric board includes an insulating substrate, a solder resist film disposed on the first main surface side with respect to the insulating substrate, and a pad that is disposed on the first main surface side with respect to the insulating substrate and that is in contact with the first bonding member, and
wherein the second end surface is in contact with the solder resist film.

17. The electric module according to claim 11, wherein the first bonding member is in contact with the second end surface.

18. The electric module according to claim 12, wherein the second bonding member is in contact with the second end surface.

19. The electric module according to claim 11, wherein the first electric board has an annular shape or a partial annular shape.

20. An electric device comprising:
a casing; and
the electric module according to claim 1 disposed inside the casing.
